(19) United States
(12) Patent Application Publication
(10) Pub. No.: US 2025/0143098 A1
(43) Pub. Date: May 1, 2025

(54) DISPLAY DEVICE AND METHOD OF FABRICATING THE SAME

(71) Applicant: Samsung Display Co., LTD., Yongin-si (KR)

(72) Inventor: Jong Hyun CHOI, Yongin-si (KR)

(21) Appl. No.: 18/752,510

(22) Filed: Jun. 24, 2024

(30) Foreign Application Priority Data
Nov. 1, 2023 (KR) 10-2023-0149119

(51) Int. Cl. H10K 59/124; H10K 59/12

(52) U.S. Cl. CPC H10K 59/124; H10K 59/1201

(57) ABSTRACT

A display device includes a first active layer of a first thin film transistor, a first insulating layer on the first active layer, a first conductive layer comprising a first gate electrode overlapping the first active layer, a second conductive layer on the first conductive layer and comprising a back gate electrode overlapping a second active layer of a second thin film transistor, a valley portion configured to penetrate at least some of the barrier layer, the buffer layer, and first to fourth insulating layers without overlapping the first active layer and the second active layer, a third conductive layer comprising a second gate electrode overlapping the second active layer, and a light emitting element electrically connected to the first thin film transistor and the second thin film transistor, respectively.

### CROSS-REFERENCE TO RELATED APPLICATION

The present application claims priority to and the benefit of Korean Patent Application No. 10-2023-0149119, filed on Nov. 1, 2023, in the Korean Intellectual Property Office, the entire disclosure of which is incorporated herein by reference.

### BACKGROUND

### 1. Field

Aspects of some embodiments of the present disclosure relate to a display device and a method of fabricating the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. Display devices include flat panel display devices such as liquid crystal display devices, field emission display devices, and organic light emitting display devices. Among flat panel display devices, in the light emitting display device, because each of pixels of a display panel includes a light emitting element capable of emitting light by itself, images can be displayed without a backlight unit providing light to the display panel.

A display device may further include pixels that emit light, scan lines, data lines, and power lines for driving the pixels, a scan driver that outputs scan signals to the scan lines, and a display driver that outputs data voltages to the data lines.

The above information disclosed in this Background section is only for enhancement of understanding of the background and therefore the information discussed in this Background section does not necessarily constitute prior art.

### SUMMARY

Aspects of some embodiments of the present disclosure include a display device capable of preventing or reducing damage to circuit elements from external impacts and preventing or reducing deterioration of the circuit elements, and a method of fabricating the same.

However, aspects of some embodiments of the present disclosure are not restricted to the one set forth herein. The above and other aspects of embodiments according to the present disclosure will become more apparent to one of ordinary skill in the art to which the present disclosure pertains by referencing the detailed description of embodiments according to the present disclosure given below.

According to some embodiments of the present disclosure, a display device comprises a barrier layer on a substrate, a buffer layer on the barrier layer, a first active layer of a first thin film transistor on the buffer layer, a first insulating layer on the first active layer, a first conductive layer on the first insulating layer and comprising a first gate electrode overlapping the first active layer, a second insulating layer on the first conductive layer, a second conductive layer on the first conductive layer and comprising a back gate electrode overlapping a second active layer of a second thin film transistor, a third insulating layer on the second conductive layer, the second active layer on the third insulating layer and overlapping the back gate electrode, a fourth insulating layer on the second active layer, a valley portion configured to penetrate at least some of the barrier layer, the buffer layer, and the first to fourth insulating layers without overlapping the first active layer and the second active layer, a third conductive layer on the fourth insulating layer and comprising a second gate electrode overlapping the second active layer, a fifth insulating layer on the third conductive layer and the fourth insulating layer and covering an inner sidewall of the valley portion, and a light emitting element on the fifth insulating layer and electrically connected to the first thin film transistor and the second thin film transistor, respectively, wherein the fifth insulating layer comprises a first inorganic layer directly on the inner sidewall of the valley portion, and a second inorganic layer containing a material different from the first inorganic layer and on the first inorganic layer.

According to some embodiments, the first inorganic layer may contain silicon oxide, and the second inorganic layer may contain silicon nitride.

According to some embodiments, the valley portion may be formed such that a part of a top surface of the barrier layer or the buffer layer is recessed, and the first inorganic layer may be in direct contact with a part of the top surface of the barrier layer or the buffer layer.

According to some embodiments, in the barrier layer, a thickness of a portion forming a bottom surface of the valley portion may be smaller than a thickness of a portion which does not overlap the valley portion.

According to some embodiments, the first inorganic layer may be in direct contact with each of the buffer layer, the first insulating layer, the second insulating layer, and the third insulating layer on the inner sidewall of the valley portion.

According to some embodiments, the valley portion may be formed to penetrate the barrier layer and expose a top surface of the substrate, and the first inorganic layer may be in direct contact with the substrate.

According to some embodiments, the display device may further comprise a filling layer which fills an inside of the valley portion and is on the second inorganic layer, wherein the filling layer may contain an organic insulating material.

According to some embodiments, the display device may further comprise wires electrically connected to at least one of the first thin film transistor or the second thin film transistor, wherein at least one of the wires may overlap the valley portion on the filling layer.

According to some embodiments, the valley portion may comprise a first valley portion and a second valley portion which overlaps the first valley portion and penetrates the fifth insulating layer, and the second valley portion may be inside the first valley portion.

According to some embodiments, a depth of the second valley portion may be smaller than a depth of the first valley portion, and a width of the second valley portion may be smaller than a width of the first valley portion.

According to some embodiments, the display device may further comprise a capping layer on the second inorganic layer on the valley portion and on an inner sidewall of the second valley portion, and a filling layer on the capping layer and filling an inside of the valley portion.

According to some embodiments, the capping layer and the filling layer may have the same maximum width.

According to some embodiments, a separation distance between the valley portion and the second active layer may be 3 μm or less.

According to some embodiments, the substrate comprises a plurality of unit pixel areas where the first thin film transistor and the second thin film transistor may be located, and the valley portion may be at a boundary between the unit pixel areas adjacent to each other.

According to some embodiments of the present disclosure, a method of fabricating a display device, comprises forming a first semiconductor layer, a first insulating layer, a first conductive layer, a second insulating layer, a second semiconductor layer, a third insulating layer, a second conductive layer, and a fourth insulating layer on a substrate, and forming a gate contact hole penetrating the third insulating layer, and a valley portion penetrating the second to fourth insulating layers, forming a second insulating layer comprising a first inorganic layer covering an inner sidewall of the valley portion, and a second inorganic layer on the first inorganic layer, and forming a plurality of contact holes penetrating at least some of the second to fourth insulating layers, and forming a plurality of bridge electrodes on the fourth insulating layer and connected to at least one of the first semiconductor layer or the second semiconductor layer through the contact holes, wherein the first inorganic layer and the second inorganic layer contain different materials.

According to some embodiments, the first inorganic layer may contain silicon oxide, and the second inorganic layer may contain silicon nitride.

According to some embodiments, a buffer layer between the substrate and the first semiconductor layer, and a barrier layer between the buffer layer and the substrate may be further formed, the valley portion is formed such that a part of a top surface of the barrier layer or the buffer layer may be recessed while penetrating the barrier layer or the buffer layer, and the first inorganic layer may be in direct contact with a part of the top surface of the barrier layer or the buffer layer.

According to some embodiments, a buffer layer between the substrate and the first semiconductor layer, and a barrier layer between the buffer layer and the substrate may be further formed, the valley portion may be formed to penetrate the buffer layer and the barrier layer, and the first inorganic layer may be in direct contact with a part of a top surface of the substrate.

According to some embodiments, in the forming of the plurality of contact holes, the first inorganic layer and the second inorganic layer may be partially penetrated inside the valley portion, and the valley portion may comprise a first valley portion, and a second valley portion penetrating the first inorganic layer and the second inorganic layer.

According to some embodiments, the method may further comprise forming a capping layer on an inner sidewall of the second valley portion and the second inorganic layer, and a filling layer filling an inside of the valley portion.

According to some embodiments, a display device according to some embodiments may include a valley portion arranged around an area where pixel circuits are located. The inner sidewall of the valley portion may be covered by an insulating layer located thereon, and a gas generated from an organic insulating material may be prevented from moving to an adjacent circuit element. Accordingly, the display device may prevent damage to circuit elements due to external impact and deterioration of the circuit element due to the gas.

In a method of fabricating a display device, a valley portion may be formed without an additional mask process.

In addition, a display device may have relatively flexible characteristics, and the valley portion may prevent or reduce instances of cracks forming in a plurality of insulating layers on the substrate when the substrate is folded.

However, the characteristics of embodiments according to the present disclosure are not limited to those illustrated above and various other characteristics are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view of a display device according to some embodiments;

FIG. 2 is a plan view illustrating the display device of FIG. 1;

FIG. 3 is a cross-sectional view taken along the line A-A′ of FIG. 2;

FIG. 4 is a plan view illustrating a display panel according to some embodiments;

FIG. 5 is a pixel circuit diagram of a sub-pixel according to some embodiments;

FIG. 6 is a pixel circuit diagram of a sub-pixel according to some embodiments;

FIG. 7 is a plan view illustrating an example arrangement of a plurality of pixel circuits located in a display area of a display device according to some embodiments;

FIG. 8 is a plan view illustrating pixel circuits located in a unit pixel area of FIG. 7;

FIG. 9 is a cross-sectional view taken along the line IX-IX′ of FIG. 8;

FIG. 10 is an enlarged view of the valley portion in FIG. 9;

FIGS. 11 to 17 are diagrams sequentially showing a part of a fabricating process of a display device according to some embodiments;

FIG. 18 is a plan view showing the arrangement of a plurality of pixels and a valley portion arranged in a display area of a display device according to some embodiments;

FIG. 19 is a cross-sectional view illustrating a part of a display device according to some embodiments;

FIG. 20 is a cross-sectional view illustrating a part of a display device according to some embodiments;

FIG. 21 is a cross-sectional view illustrating a part of a display device according to some embodiments; and

FIGS. 22 to 26 are diagrams sequentially showing a part of the fabricating process of the display device of FIG. 21.

### DETAILED DESCRIPTION

Aspects of some embodiments of the present disclosure will now be described more fully hereinafter with reference to the accompanying drawings, in which aspects of some embodiments according to the present disclosure are shown. This invention may, however, be embodied in different forms and should not be construed as limited to the embodiments set forth herein. Rather, these embodiments are provided so that this disclosure will be thorough and complete, and will more fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Hereinafter, aspects of some embodiments will be described with reference to the accompanying drawings.

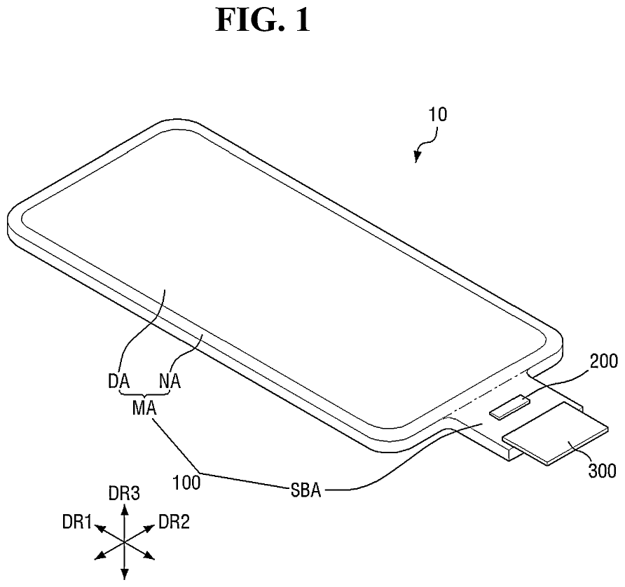

FIG. 1 is a perspective view of a display device according to some embodiments.

Referring to FIG. 1, a display device 10 is a device for displaying moving images (e.g., video images) or still images (e.g., static images). The display device 10 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be a light emitting display device such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). In the following, embodiments in which the display device 10 is an organic light emitting display device is described, but the type of display device 10 is not limited thereto.

According to some embodiments, the display device 10 may be formed flat. For example, the display device 10 may be formed substantially flat on a plane defined by a first direction DR1 and a second direction DR2, and may have a thickness (e.g., a set or predetermined thickness) (or height) in a third direction DR3. According to some embodiments, the display device 10 may include a curved surface in at least a part including an edge region and the like. In addition, the display device 10 may be formed to be flexible so that it can be curved, bent, folded, or rolled.

According to some embodiments, with respect to the image display surface of the display device 10, the first direction DR1 may be a lengthwise direction, a column direction, or a vertical direction, and the second direction DR2 may be a direction intersecting the first direction DR1, for example, a widthwise direction, a row direction, or a horizontal direction. The third direction DR3 may be a thickness direction or a height direction of the display device 10.

The display device 10 may include a display panel 100, a driver 200, and a circuit board 300.

The display panel 100 may include a main region MA including a display area DA in which images are displayed, and a sub-region SBA located on one side of the main region MA.

The main region MA may include the display area DA and a non-display area NA surrounding (e.g., in a periphery or outside a footprint of) the display area DA. The display area DA may be positioned in the center of the main region MA and occupy most of the area in the main region MA. The non-display area NA may be positioned at an edge of the main region MA and may be in contact with the sub-region SBA.

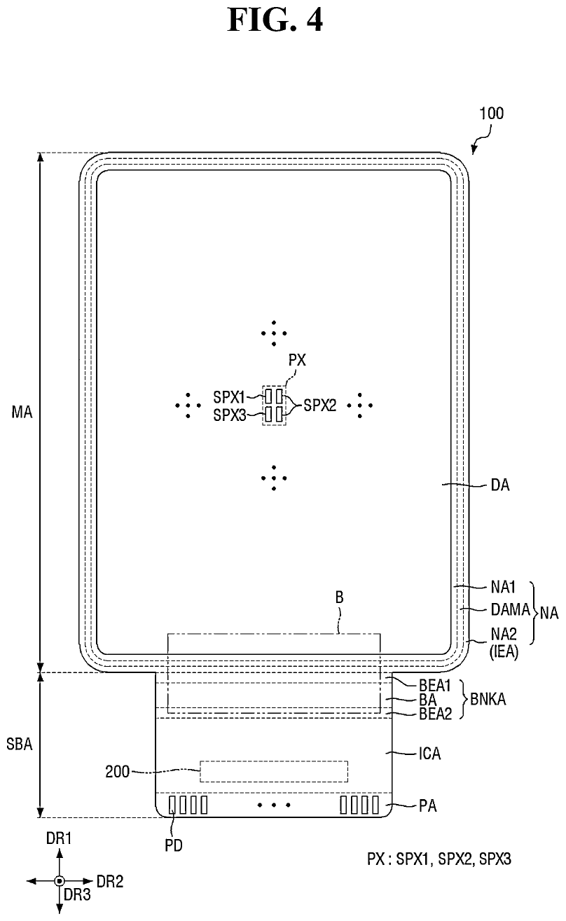

The display area DA may be an area where pixels (e.g., pixels PX in FIG. 4) are arranged and an image is displayed by the pixels PX. According to some embodiments, the display area DA may be further provided with sensing patterns (e.g., touch electrodes) for detecting a touch input and the like, and the display area DA may include a sensing area for detecting a touch input by the sensing patterns.

According to some embodiments, the display area DA may include a long side in the first direction DR1 and a short side in the second direction DR2 and may be formed as a plane having an approximately rectangular shape. A corner portion at which the long side and the short side of the display area DA meet may be rounded or right-angled. The shape of the display area DA may be variously changed according to embodiments. For example, the display area DA may be formed in a polygonal shape other than a quadrilateral shape, a circular shape, an elliptical shape, or the like.

The non-display area NA may be located immediately around (e.g., in a periphery or outside a footprint of) the display area DA. The non-display area NA may surround (e.g., in a periphery or outside a footprint of) the display area DA. An embedded circuit may be located in the non-display area NA. For example, an embedded circuit including a scan driving circuit or the like may be located in the non-display area NA positioned on one side (e.g., the left side or the right side) or both sides of the display area DA.

The sub-region SBA may be located on one side of the main region MA. For example, the sub-region SBA may be a region protruding in the first direction DR1 from one side of the main region MA. For example, the sub-region SBA may protrude in the first direction DR1 from the lower end of the main region MA. According to some embodiments, the sub-region SBA may have a narrower width than the main region MA. For example, with respect to the second direction DR2, the sub-region SBA may have a narrower width than the main region MA.

Wires and pads may be located in the sub-region SBA. For example, in the sub-region SBA, the wires and pads connected to the pixels and/or the embedded circuit positioned in the main region MA and to the driver 200 and/or the circuit board 300 positioned in the sub-region SBA may be located. In describing embodiments, the term “connect” may include electrical connection and/or physical connection.

According to some embodiments, the driver 200 (e.g., the display driving circuit) may be mounted in the sub-region SBA. The circuit board 300 may be located on a portion of the sub-region SBA.

The driver 200 may include a data driving circuit to drive pixels. According to some embodiments, the driver 200 may be formed as an integrated circuit chip (IC) and located in the sub-region SBA. According to some embodiments, the driver 200 may be located on the circuit board 300 on the sub-region SBA or may be located on another circuit board connected to the display panel 100 through the circuit board 300.

The circuit board 300 may be located on a part of the sub-region SBA. For example, the circuit board 300 may be bonded on the pads positioned on a portion (e.g., a lower edge) of the sub-region SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible film such as a flexible printed circuit board (FPCB), a printed circuit board (PCB), or a chip on film (COF), but is not limited thereto.

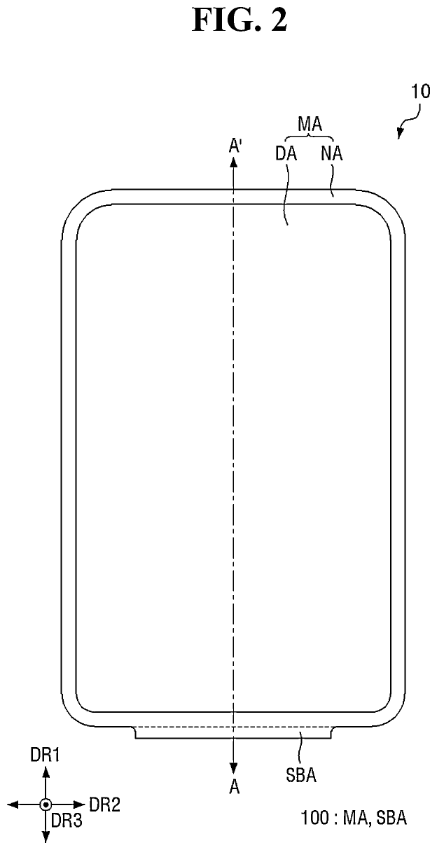

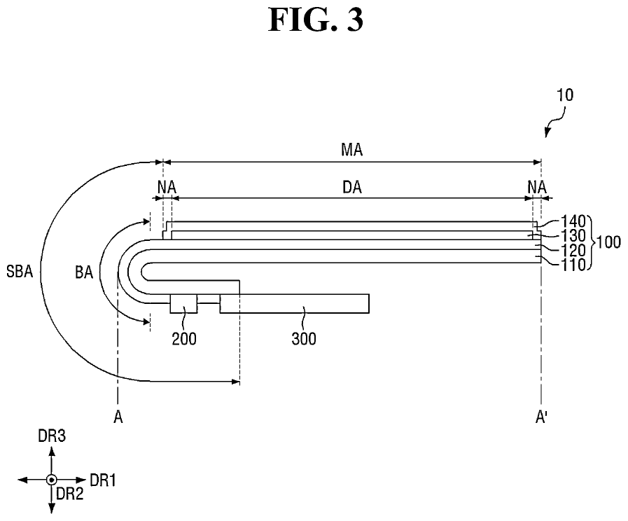

FIG. 2 is a plan view illustrating the display device of FIG. 1. FIG. 3 is a cross-sectional view taken along the line A-A′ of FIG. 2.

FIG. 1 illustrates the display device 10 unfolded without bending, and FIGS. 2 and 3 illustrate the display device 10 bent in the sub-region SBA. FIG. 1 shows the sub-region SBA unfolded alongside the main region MA, and FIGS. 2 and 3 show a part of the sub-region SBA in a bent state.

Referring to FIGS. 2 and 3, the display panel 100 may include a substrate 110 including the main region MA and the sub-region SBA, and a circuit layer 120, a light emitting element layer 130, and an encapsulation layer 140 sequentially arranged on the substrate 110. The circuit layer 120 may also be positioned in the main region MA and the sub-region SBA on the substrate 110. The light emitting element layer 130 and the encapsulation layer 140 may be positioned on a part of the substrate 110 and the circuit layer 120. For example, the light emitting element layer 130 and the encapsulation layer 140 may be positioned in the main region MA.

According to some embodiments, the display device 10 may further include an additional element located on the display panel 100. For example, the display device 10 may further include at least one of a sensor layer (e.g., a touch sensor layer), a polarization layer, a color filter layer, or a protective layer (e.g., a window) located on the encapsulation layer 140. Each of the sensor layer, the polarization layer, the color filter layer, and/or the protective layer may be fabricated integrally with the display panel 100 or may be fabricated separately from the display panel 100 and attached to the display panel 100 through an adhesive layer or the like.

The substrate 110 may include an insulating material such as a polymer resin. For example, the substrate 110 may be made of polyimide or another insulating material. The substrate 110 may be a flexible substrate that can be transformed, such as bending, folding, or rolling. Alternatively, the substrate 110 may include an insulating material such as glass.

The circuit layer 120 may include pixel circuits and wires. For example, the circuit layer 120 may include circuit elements (e.g., pixel transistors and capacitors) constituting a pixel circuit for each pixel, and wires connected to the pixels. According to some embodiments, the circuit layer 120 may further include circuit elements constituting an embedded circuit, such as a scan driving circuit, and wires connected to the embedded circuit.

The light emitting element layer 130 may include light emitting elements located in emission areas of the pixels. For example, each of the pixels may include at least one light emitting element and a pixel circuit connected to the light emitting element. Each of the pixels may be located in a pixel region, including the emission area where the light emitting element is located and a pixel circuit area where the pixel circuit is located. The emission area and the pixel circuit area of each pixel may overlap each other, but embodiments according to the present disclosure are not limited thereto.

In describing the embodiments, the circuit layer 120 and the light emitting element layer 130 are separately described, but the embodiments are not limited thereto. For example, the circuit layer 120 and the light emitting element layer 130 may be integrated.

The encapsulation layer 140 may cover the light emitting element layer 130 and may extend to the non-display area NA to be in contact with the circuit layer 120. According to some embodiments, the encapsulation layer 140 may have a multilayer structure including at least two inorganic encapsulation layers overlapping each other and at least one organic encapsulation layer interposed between the inorganic encapsulation layers.

According to some embodiments, the display panel 100 may be bent in a bending area BA. The bending area BA may be a part of the sub-region SBA and may be spaced apart from the main region MA.

The substrate 110 and the circuit layer 120 may be bent in the bending area BA corresponding to a partial section of the sub-region SBA. Accordingly, the bezel area recognized by a user as the non-display area NA may be reduced or minimized.

FIG. 4 is a plan view illustrating a display panel according to some embodiments. FIG. 4 shows the display panel 100 in an unbent and unfolded state.

Referring to FIG. 4, the display panel 100 may include the main region MA and the sub-region SBA. The main region MA may include the display area DA and the non-display area NA, and the sub-region SBA may include a bank area BNKA, a driving circuit mounting area ICA, and a pad area PA.

The display area DA may be an area where a plurality of pixels PX are located. The pixels PX and wires (or some of the wires) connected to the pixels PX may be located in the display area DA.

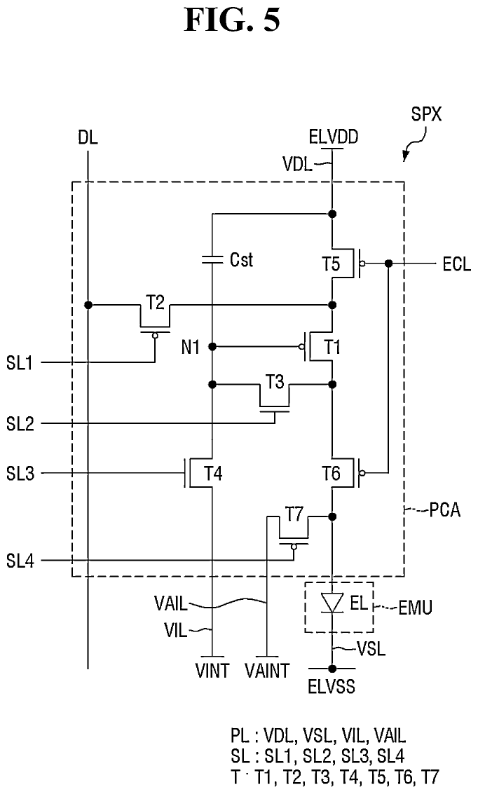

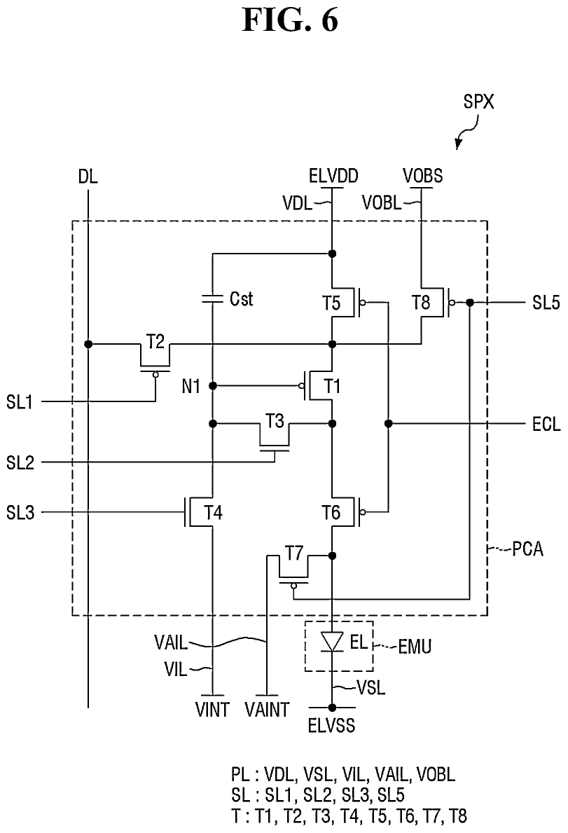

The pixels PX may be provided in the circuit layer 120 and the light emitting element layer 130 of the display panel 100. As an example, each pixel PX may include a pixel circuit (e.g., a pixel circuit PCA of FIG. 5 or 6) including circuit elements located on the circuit layer 120 and a light emitting element (e.g., a light emitting element EL of FIG. 5 or FIG. 6) located on the light emitting element layer 130.

The pixels PX may include at least two color sub-pixels SPX that emit light of different colors. For example, the pixels PX may include first color sub-pixels SPX1 emitting light of a first color (e.g., red light), second color sub-pixels SPX2 emitting light of a second color (e.g., green light), and third color sub-pixels SPX3 emitting light of a third color (e.g., blue light).

At least one first color sub-pixel SPX1, at least one second color sub-pixel SPX2, and at least one third color sub-pixel SPX3 adjacent to each other may constitute one unit pixel PX. For example, one first color sub-pixel SPX1, two second color sub-pixels SPX2, and one third color sub-pixel SPX3 adjacent to each other may constitute one unit pixel PX. Each unit pixel PX may emit light of various colors, including white light, by color mixing of light emitted from the sub-pixels SPX1, SPX2, and SPX3 constituting the unit pixel PX. According to some embodiments, the first color sub-pixels SPX1 and the third color sub-pixels SPX3 may be arranged alternately in the first direction DR1 and/or the second direction DR2, and the second color sub-pixels SPX2 may be arranged continuously and/or sequentially in the first direction DR1. The type, shape, and/or arrangement structure of the sub-pixels SPX1, SPX2, and SPX3 may be changed depending on the embodiments. In addition, the type, number, ratio, and/or arrangement structure of the sub-pixels SPX1, SPX2, and SPX3 constituting each unit pixel PX may also be changed depending on the embodiments.

The encapsulation layer 140 may be located on the pixels PX. For example, the encapsulation layer 140 may be provided in at least the display area DA to cover the pixels PX, and a part of the encapsulation layer 140 may extend into the non-display area NA.

Wires may be provided in the circuit layer 120 and may be positioned in the display area DA and the non-display area NA. In addition, wires may be positioned also in the sub-region SBA. For example, the wires may extend from the sub-region SBA through the non-display area NA to the display area DA.

The non-display area NA may be located around the display area DA. For example, the non-display area NA may be an edge area of the main region MA positioned outside the display area DA.

The non-display area NA may include a dam area DAMA spaced apart from the display area DA, a first non-display area NA1 between the display area DA and the dam area DAMA, and a second non-display area NA2 outside the dam area DAMA. The dam area DAMA may be an area in which a dam surrounding the display area DA is located. The second non-display area NA2 may include an inorganic encapsulation area IEA (also referred to as a “bonding area”) in which the inorganic encapsulation layers of the encapsulation layer 140 are bonded to each other.

The sub-region SBA may include the bank area BNKA, the driving circuit mounting area ICA, and the pad area PA sequentially arranged on one side of the main region MA. Wires (or parts of wires), banks, and the pads PD may be located in the sub-region SBA. At least some of the wires may extend into the main region MA and be connected to the pixels PX.

The bank area BNKA may be an area in which a bank including at least one organic layer is located. According to some embodiments, the bank area BNKA may include the bending area BA. For example, the bank area BNKA may include the bending area BA spaced apart from the main region MA, and a first edge area BEA1 and a second edge area BEA2 positioned on both sides of the bending area BA in the first direction DR1. The bank may be provided in the bending area BA and the peripheral areas thereof (e.g., the first edge area BEA1 and the second edge area BEA2 of the bank area BNKA) to cover wires passing through the bending area BA. The display panel 100 may be bent in the bending area BA such that a part of the sub-region SBA may be positioned behind the main region MA.

The driving circuit mounting area ICA may be an area in which the driver 200 is located. Pads for connecting at least some of the wires to the driver 200 may be located in the driving circuit mounting area ICA. For example, in the driving circuit mounting area ICA, input pads for connecting the driver 200 to the specific pads (e.g., data input pads) of the pad area PA and output pads for connecting the driver 200 to the pixels PX may be arranged.

In some embodiments, the driver 200 may not be located on the display panel 100. In this case, the display panel 100 may not include the driving circuit mounting area ICA, and only wires may be located in an area between the bank area BNKA and the pad area PA.

The pad area PA may be an area where the pads PD for connecting the display panel 100 and/or the driver 200 to the circuit board 300 and the like are located. The circuit board 300 may be located or bonded on the pad area PA.

A plurality of pads PD including power pads and signal pads connected to the pixels PX, the driver 200, and/or the embedded circuit may be located in the pad area PA. Power voltages for driving the pixels PX, the driver 200, and/or the embedded circuit or the like may be supplied to the power pads. Driving signals and/or image data for driving the pixels PX, the driver 200, and/or the embedded circuit or the like may be supplied to the signal pads. The type, location, arrangement order, and/or number of the pads PD may be variously changed according to embodiments.

FIG. 5 is a pixel circuit diagram of a sub-pixel according to some embodiments. FIG. 6 is a pixel circuit diagram of a sub-pixel according to some embodiments.

FIGS. 5 and 6 illustrate different embodiments related to the pixel circuit PCA and wires connected to the pixel circuit PCA. The configuration of the pixel circuit PCA and the type and number of wires connected to the pixel circuit PCA may be variously changed according to embodiments.

FIG. 5 illustrates embodiments in which each pixel circuit PCA includes first to seventh transistors T1 to T7. According to some embodiments, scan lines SL connected to the sub-pixel SPX of FIG. 5 may include a first scan line SL1, a second scan line SL2, a third scan line SL3, and a fourth scan line SL4, and power lines PL connected to the sub-pixel SPX of FIG. 5 may include a first pixel power line VDL, a second pixel power line VSL, a first initialization power line VIL, and a second initialization power line VAIL. The sub-pixel SPX of FIG. 5 may be further connected to an emission control line ECL.

FIG. 6 illustrates embodiments in which each pixel circuit PCA includes first to eighth transistors T1 to T8. According to some embodiments, the scan lines SL connected to the sub-pixel SPX of FIG. 6 may include the first scan line SL1, the second scan line SL2, the third scan line SL3, and a fifth scan line SL5, and the power lines PL connected to the sub-pixel SPX of FIG. 6 may include the first pixel power line VDL, the second pixel power line VSL, the first initialization power line VIL, the second initialization power line VAIL, and a bias power line VOBL. The sub-pixel SPX of FIG. 6 may be further connected to the emission control line ECL.

Referring to FIG. 5, the sub-pixel SPX may include a light emitting unit EMU including at least one light emitting element EL and the pixel circuit PCA (also referred to as a “pixel driver”) connected to the light emitting unit EMU.

The light emitting element EL may be connected between the pixel circuit PCA and the second pixel power line VSL to which the second pixel power voltage ELVSS is applied. According to some embodiments, the second pixel power voltage ELVSS may be a low potential pixel driving voltage. The light emitting element EL, which is a light source of the pixel PX, may emit light in response to the driving current supplied from the pixel circuit PCA.

The light emitting element EL may be an organic light emitting diode, but embodiments according to the present disclosure are not limited thereto. For example, the light emitting element EL may be an inorganic light emitting element, a quantum dot light emitting element, or another type of light emitting element.

The pixel circuit PCA may control the light emitting timing and luminance of the light emitting element EL by controlling the driving current supplied to the light emitting element EL. The pixel circuit PCA may include at least one pixel transistor T and a capacitor Cst. According to some embodiments, the pixel circuit PCA may include pixel transistors T including the first to seventh transistors T1 to T7.

The first transistor T1 may include a gate electrode connected to the first node N1, a first electrode electrically connected to the first pixel power line VDL through the fifth transistor T5, and a second electrode electrically connected to the light emitting unit EMU through the sixth transistor T6. One of the first electrode and the second electrode may be a source electrode and the other one may be a drain electrode. The first transistor T1 may control a source-drain current (hereinafter referred to as a “driving current”) flowing between the first electrode and the second electrode according to the voltage (e.g., the voltage of the first node N1 corresponding to the voltage of the data signal) applied to the gate electrode. For example, the first transistor T1 may be a driving transistor of the sub-pixel SPX.

The second transistor T2 may include a gate electrode connected to the first scan line SL1, a first electrode connected to the data line DL, and a second electrode connected to the first electrode of the first transistor T1. The second transistor T2 may be turned on by the first scan signal supplied to the first scan line SL1 to electrically connect the first electrode of the first transistor T1 to the data line DL. When the second transistor T2 is turned on, the voltage of the data signal supplied to the data line DL may be applied to the first electrode of the first transistor T1.

The third transistor T3 may include a gate electrode connected to the second scan line SL2, a first electrode connected to the second electrode of the first transistor T1, and a second electrode connected to a gate electrode (or the first node N1) of the first transistor T1. The third transistor T3 may be turned on by the second scan signal supplied to the second scan line SL2 to electrically connect the gate electrode of the first transistor T1 to the second electrode. When the third transistor T3 is turned on, the first transistor T1 may be driven as a diode.

The fourth transistor T4 may include a gate electrode connected to the third scan line SL3, a first electrode connected to the gate electrode of the first transistor T1, and a second electrode connected to the first initialization power line VIL. The fourth transistor T4 may be turned on by the third scan signal supplied to the third scan line SL3 to electrically connect the gate electrode of the first transistor T1 to the first initialization power line VIL. When the fourth transistor T4 is turned on, a first initialization voltage VINT (e.g., the gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on by the emission control signal supplied to the emission control line ECL, and thus may electrically connect the first electrode of the first transistor T1 to the first pixel power line VDL to which a first pixel power voltage ELVDD is applied. When the fifth transistor T5 is turned on, the first pixel power voltage ELVDD may be applied to the first electrode of the first transistor T1. According to some embodiments, the first pixel power voltage ELVDD may be a high potential pixel driving voltage.

The sixth transistor T6 may include the gate electrode connected to the emission control line ECL, the first electrode connected to the second electrode of the first transistor T1, and the second electrode connected to the light emitting element EL. The sixth transistor T6 may be turned on by the emission control signal supplied to the emission control line ECL to electrically connect the first transistor T1 to the light emitting element EL. When all of the fifth transistor T5 and the sixth transistor T6 are turned on, the driving current having a magnitude corresponding to the voltage of the gate electrode of the first transistor T1 may flow through the light emitting element EL.

The seventh transistor T7 may include a gate electrode connected to the fourth scan line SL4, a first electrode connected to the anode electrode of the light emitting element EL, and a second electrode connected to the second initialization power line VAIL. The seventh transistor T7 may be turned on by the fourth scan signal supplied to the fourth scan line SL4 to electrically connect the anode electrode of the light emitting element EL to the second initialization power line VAIL. The fourth scan signal may be the same signal as or a different signal from the first scan signal. When the seventh transistor T7 is turned on, the second initialization voltage VAINT (e.g., an anode initialization voltage) of the second initialization power line VAIL may be applied to the anode electrode of the light emitting element EL.

The capacitor Cst may be connected between the gate electrode of the first transistor T1 and the first pixel power line VDL. The capacitor Cst may be charged with a voltage corresponding to the voltage of the data signal applied to the gate electrode of the first transistor T1.

The active layer (e.g., a semiconductor pattern including a channel region) of each of the pixel transistors T (e.g., the first to seventh transistors T1 to T7) may include one semiconductor material of polysilicon, amorphous silicon, and an oxide semiconductor. According to some embodiments, some of the pixel transistors T and some others thereof may be formed of transistors of different conductivity types. In addition, some of the pixel transistors T and some others thereof may include different types of semiconductor materials.

For example, the first, second, fifth, sixth, and seventh transistors T1, T2, T5, T6, and T7 may be formed of P-type transistors (e.g., P-type MOSFETs) including the respective active layers formed of polysilicon, and the third and fourth transistors T3 and T4 may be formed of N-type transistors (e.g., N-type MOSFETs) including the respective active layers formed of an oxide semiconductor. According to some embodiments, transistors including the respective active layers formed of polysilicon and transistors including the respective active layers formed of an oxide semiconductor may be arranged on different layers in the circuit layer 120.

Referring to FIG. 6 in addition to FIG. 5, the pixel circuit PCA may further include the eighth transistor T8. The eighth transistor T8 may include a gate electrode connected to the fifth scan line SL5, a first electrode connected to the bias power line VOBL, and a second electrode connected to the first electrode of the first transistor T1. The eighth transistor T8 may be turned on by the fifth scan signal supplied to the fifth scan line SL5 to electrically connect the first electrode of the first transistor T1 to the bias power line VOBL. When the eighth transistor T8 is turned on, the bias voltage VOBS supplied to the bias power line VOBL may be applied to the first electrode of the first transistor T1. According to some embodiments, the bias voltage VOBS may have a voltage level suitable for compensating for the hysteresis characteristic of the first transistor T1. As the eighth transistor T8 is turned on, the first electrode of the first transistor T1 may be initialized to the bias voltage VOBS.

According to some embodiments as illustrated in FIG. 6, the gate electrode of the seventh transistor T7 may be connected to the fifth scan line SL5. Accordingly, the seventh transistor T7 may be turned on by the fifth scan signal supplied to the fifth scan line SL5 to connect the anode electrode of the light emitting element EL to the second initialization power line VAIL.

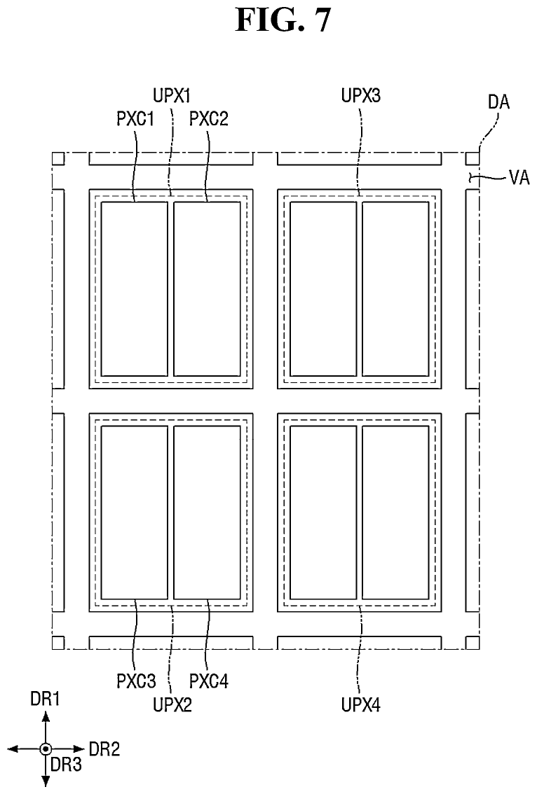

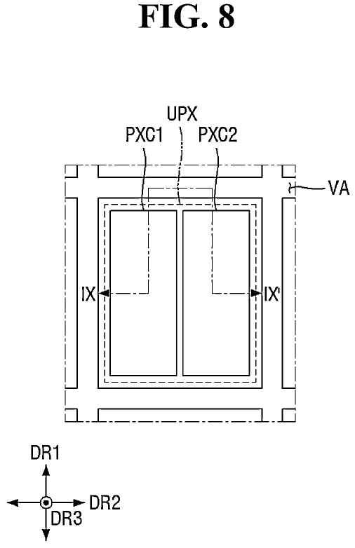

FIG. 7 is a plan view illustrating an arrangement of a plurality of pixel circuits located in a display area of a display device according to some embodiments. FIG. 8 is a plan view illustrating pixel circuits located in a unit pixel area of FIG. 7.

Referring to FIGS. 7 and 8, the display device 10 may include a plurality of pixel circuits PXC (PXC1, PXC2, PXC3, and PXC4) located in the display area DA. Each of the plurality of pixel circuits PXC may be electrically connected to the light emitting element EL included in the sub-pixels SPX1, SPX2, and SPX3. A plurality of circuit elements included in the pixel circuit PXC may be applied with electrical signals for the light emitting element EL to emit light.

The plurality of pixel circuits PXC may be arranged in the first direction DR1 and the second direction DR2. For example, the two pixel circuits PXC adjacent to each other in the second direction DR2 may constitute one unit pixel area UPX (UPX1, UPX2, UPX3, and UPX4), and may be arranged in the first direction DR1 and the second direction DR2. The first pixel circuit PXC1 and the second pixel circuit PXC2 adjacent to each other in the second direction DR2 may constitute the one first unit pixel area UPX1. The third pixel circuit PXC3 and the fourth pixel circuit PXC4 adjacent to each other in the second direction DR2 may constitute the one second unit pixel area UPX2. The first unit pixel area UPX1 and the second unit pixel area UPX2 may be arranged in the first direction DR1. Each of the third unit pixel area UPX3 and the fourth unit pixel area UPX4 may include two pixel circuits adjacent to each other in the second direction DR2, and may be arranged in the first direction DR1. The first unit pixel area UPX1 and the second unit pixel area UPX2 may be arranged in the second direction DR2 with respect to the third unit pixel area UPX3 and the fourth unit pixel area UPX4, respectively.

The plurality of wires, conductive patterns, and semiconductor layers constituting the pixel circuit may repeat the same patterns with respect to the one unit pixel area UPX rather than the pixel circuit. For example, the arrangement structure of the wires, conductive patterns, and semiconductor layers of the first unit pixel area UPX1 may have the same arrangement structure in the second unit pixel area UPX2, the third unit pixel area UPX3, and the fourth unit pixel area UPX4. Each of the first pixel circuit PXC1 and the second pixel circuit PXC2 may have a symmetric structure in the arrangement of the conductive patterns and the semiconductor layers, and the conductive patterns and patterns of semiconductor layers constituting the two pixel circuits PXC1 and PXC2 may be repeatedly arranged on the entire surface of the display area DA.

According to some embodiments, the display device 10 may include a valley portion VA arranged to surround the unit pixel area UPX. The valley portion VA may surround the one unit pixel area UPX and may surround a plurality of unit pixel areas UPX on the entire surface of the display area DA. The valley portion VA may be located at the boundary of the plurality of unit pixel areas UPX arranged in the first direction DR1 and the second direction DR2. The valley portion VA may be arranged to extend in the first direction DR1 and the second direction DR2, and the two pixel circuits PXC may be located in an area that the valley portions VA surround by intersecting each other. The plurality of unit pixel areas UPX may be spaced apart from each other with the valley portion VA located therebetween, and may be isolated within an area surrounded by the valley portion VA.

The valley portion VA may be formed to penetrate a plurality of conductive layers constituting the pixel circuit PXC and an interlayer insulating layer located between the semiconductor layers. The valley portion VA may prevent or reduce transmission of external impact applied to the display device 10 to elements of the pixel circuit. In addition, the display device 10 may include the valley portion VA surrounding the area in which the pixel circuits PXC are located, so that when the display device 10 including the flexible substrate 110 is folded, cracks that may form on a plurality of insulating layers may be prevented or reduced. However, embodiments according to the present disclosure are not limited thereto. In some embodiments, the valley portion VA may not completely surround the unit pixel area UPX, and may be formed in a pattern that extends in one direction and is spaced apart from another valley portion VA.

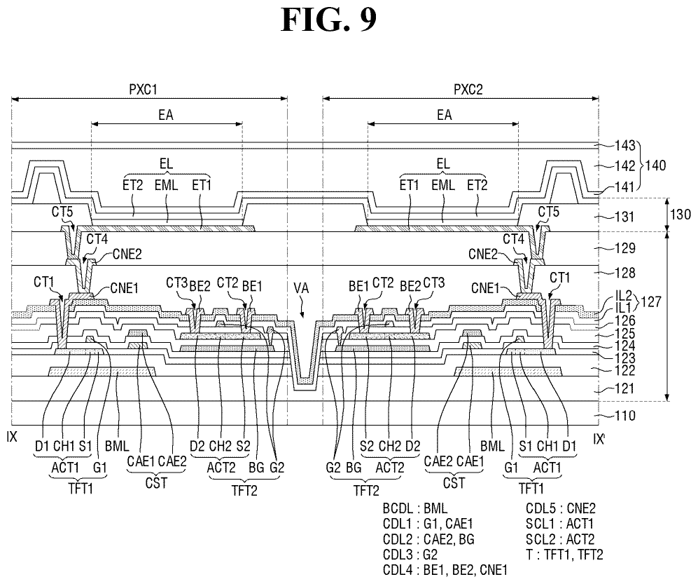

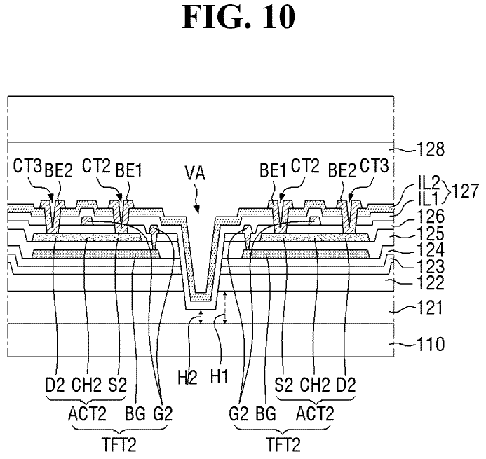

FIG. 9 is a cross-sectional view taken along the line IX-IX′ of FIG. 8. FIG. 10 is an enlarged view of the valley portion in FIG. 9.

FIG. 9 schematically illustrates a cross section of a part of the display area DA corresponding to an area in which the one unit pixel area UPX is located and positioned. FIG. 9 illustrates a cross section crossing a part of the first pixel circuit PXC1 and the second pixel circuit PXC2 adjacent to each other in the second direction DR2. FIG. 10 is an enlarged view of the valley portion VA in FIG. 9.

Referring to FIG. 9, the display panel 100 may include the substrate 110, the circuit layer 120 located on the substrate 110, the light emitting element layer 130, and the encapsulation layer 140. The circuit layer 120, the light emitting element layer 130, and the encapsulation layer 140 may be sequentially arranged or stacked on the substrate 110 along the third direction DR3.

The substrate 110 may be made of a material having a flexible characteristic capable of bending, folding, rolling, or the like. The substrate 110 may be formed of an insulating material such as a polymer resin. For example, the substrate 110 may be made of polyimide.

The circuit layer 120 may include the pixel circuit PXC and wires. For example, the circuit layer 120 may include circuit elements (e.g., the pixel transistors T and the capacitor Cst) constituting the pixel circuit PXC of each sub-pixel SPX, and wires (e.g., various power lines and signal lines including the power lines PL, the scan lines SL, the emission control lines ECL, and the data lines DL) electrically connected to the sub-pixels SPX.

Among elements that may be provided on the circuit layer 120, FIG. 9 illustrates a first thin film transistor TFT1 (also referred to as a “first pixel transistor”) included in the pixel circuit PXC of each sub-pixel SPX, a second thin film transistor TFT2 (also referred to as a “second pixel transistor”), and the capacitor Cst. The first thin film transistor TFT1 may represent first type transistors (e.g., P-type transistors) including a first semiconductor material (e.g., polysilicon) among the pixel transistors T constituting each of the pixel circuits PXC. For example, the first thin film transistor TFT1 may be one of the first, second, fifth, sixth, seventh, and/or eighth transistors T1, T2, T5, T6, T7, and/or T8. FIG. 9 illustrates, as the first thin film transistor TFT1, one transistor (e.g., the sixth transistor T6 of FIG. 5 or FIG. 6) connected to the light emitting element EL through at least one connection electrode (e.g., a first connection electrode CNE1 and a second connection electrode CNE2) among the first type transistors. The second thin film transistor TFT2 may represent second type transistors (e.g., N-type transistors) including a second semiconductor material (e.g., oxide semiconductor) among the pixel transistors T. For example, the second thin film transistor TFT2 may be one of the third and fourth transistors T3 and T4.

Cross sections of the sub-pixels SPX may be variously changed according to each of the sub-pixels SPX and the type and/or structure of the display panel 100 including the sub-pixel SPX. For example, positions and order of formation of the first thin film transistor TFT1, the second thin film transistor TFT2, and the capacitor Cst may vary according to embodiments.

The circuit layer 120 may include semiconductor layers for forming circuit elements, wires, or the like, conductive layers, and insulating layers located between and/or around the conductive layers and the semiconductor layers. For example, the circuit layer 120 may include a first semiconductor layer SCL1 (e.g., a polysilicon semiconductor layer), a first insulating layer 123 (e.g., a first gate insulating layer), a first conductive layer CDL1 (e.g., a first gate conductive layer), a second insulating layer 124 (e.g., a second gate insulating layer), a second conductive layer CDL2 (e.g., a second gate conductive layer), a third insulating layer 125 (e.g., a first interlayer insulating layer), a second semiconductor layer SCL2 (e.g., an oxide semiconductor layer), a fourth insulating layer 126 (e.g., a third gate insulating layer), a third conductive layer CDL3 (e.g., a third gate conductive layer), a fifth insulating layer 127 (e.g., a second interlayer insulating layer), a fourth conductive layer CDL4 (e.g., a first source-drain conductive layer), and a sixth insulating layer 128 (e.g., a first via layer or a first planarization layer) sequentially located on the substrate 110 with respect to the third direction DR3. According to some embodiments, the circuit layer 120 may further include a fifth conductive layer CDL5 (e.g., a second source-drain conductive layer) and a seventh insulating layer 129 (e.g., a second via layer or a second planarization layer) sequentially located on the sixth insulating layer 128. According to some embodiments, the circuit layer 120 may further include a lower conductive layer BCDL located between the substrate 110 and the first semiconductor layer SCL1, a barrier layer 121 located between the substrate 110 and the lower conductive layer BCDL, and a buffer layer 122 located between the lower conductive layer BCDL and the first semiconductor layer SCL1.

The barrier layer 121 may be located on the substrate 110. The barrier layer 121 may protect elements located on the circuit layer 120 and the light emitting element layer 130 from moisture permeating through the substrate 110 that is susceptible to moisture permeation. The barrier layer 121 may include at least one inorganic layer containing an inorganic insulating material (e.g., silicon nitride, silicon oxide, silicon oxynitride, titanium oxide, aluminum oxide, or another inorganic insulating material). The material of the barrier layer 121 may be variously changed according to embodiments.

The lower conductive layer BCDL may be located on the barrier layer 121. The lower conductive layer BCDL may include a lower metal layer BML overlapping the active layer (e.g., a first active layer ACT1 and/or a second active layer ACT2) of the at least one pixel transistor T, and/or at least one wire (or a part of the at least one wire). FIG. 9 illustrates that the lower metal layer BML overlaps only the first active layer ACT1 of the first thin film transistor TFT1 and the capacitor electrodes CAE1 and CAE2 of the capacitor Cst, but the present disclosure is not limited thereto. For example, the lower metal layer BML may be patterned into an appropriate size and/or shape as needed and located on a part of the pixel circuit PXC, or may be located on the entire surface of the pixel circuit PXC. For example, the lower metal layer BML may be located only in a part of the pixel area to overlap the first transistor T1 illustrated in FIGS. 5 and 6. According to some embodiments, the lower metal layer BML may also be utilized as a light blocking pattern and/or a back-gate electrode of at least one pixel transistor T, or the like.

The buffer layer 122 may be located on the lower conductive layer BCDL to cover the lower conductive layer BCDL. The buffer layer 122 may include at least one inorganic layer containing an inorganic insulating material.

The first thin film transistor TFT1, the second thin film transistor TFT2, and the capacitor Cst may be located on one surface of the substrate 110 including the buffer layer 122. The first thin film transistor TFT1 may include the first active layer ACT1 and a first gate electrode G1. The second thin film transistor TFT2 may include the second active layer ACT2 and a second gate electrode G2. According to some embodiments, the second thin film transistor TFT2 may include a back-gate electrode BG. The capacitor Cst may include a first capacitor electrode CAE1 and a second capacitor electrode CAE2.

The first semiconductor layer SCL1 may be located on the buffer layer 122. The first semiconductor layer SCL1 may include the first active layer ACT1 of the first thin film transistor TFT1. For example, the first semiconductor layer SCL1 may include the first active layer ACT1 of each of the first, second, fifth, sixth, seventh, and/or eighth transistors T1, T2, T5, T6, T7, and/or T8.

The first active layer ACT1 may be provided on the first semiconductor layer SCL1 and may include a first semiconductor material (e.g., polysilicon). The first active layer ACT1 may include a first channel region CH1, a first source region S1, and a first drain region D1. The first channel region CH1 may overlap the first gate electrode G1 in the third direction DR3. The first source region S1 may be located on one side of the first channel region CH1, and the first drain region D1 may be located on the other side of the first channel region CH1. The first source region S1 and the first drain region D1 may be regions formed to have conductivity by doping ions or impurities into a semiconductor for forming the first active layer ACT1. According to some embodiments, the first source region S1 may be a source electrode of the first thin film transistor TFT1. According to some embodiments, the first thin film transistor TFT1 may include a separate source electrode connected to the first source region S1. According to some embodiments, the first drain region D1 may be a drain electrode of the first thin film transistor TFT1. According to some embodiments, the first thin film transistor TFT1 may include a separate drain electrode connected to the first drain region D1.

The first insulating layer 123 may be located on the first semiconductor layer SCL1. The first insulating layer 123 may cover the first semiconductor layer SCL1.

The first conductive layer CDL1 may be located on the first insulating layer 123. The first conductive layer CDL1 may include the first gate electrode G1 of the first thin film transistor TFT1. The first gate electrode G1 may overlap a part of the first active layer ACT1 (e.g., the first channel region CH1). According to some embodiments, the first conductive layer CDL1 may further include at least one wire (or a part of the at least one wire), a conductive pattern (e.g., a bridge pattern), and/or a capacitor electrode. For example, the first conductive layer CDL1 may further include the first capacitor electrode CAE1 of the capacitor Cst.

According to some embodiments, the first capacitor electrode CAE1 may be integrally formed with the gate electrode of at least one first thin film transistor TFT1. For example, the first capacitor electrode CAE1 may be integrally formed with the gate electrode of the first transistor T1 illustrated in FIGS. 5 and 6. For example, the first capacitor electrode CAE1 and the gate electrode of the first transistor T1 may be formed as one conductive pattern, and the second capacitor electrode CAE2 may overlap the conductive pattern.

The second insulating layer 124 may be located on the first conductive layer CDL1. The second insulating layer 124 may cover the first conductive layer CDL1.

The second conductive layer CDL2 may be located on the second insulating layer 124. The second conductive layer CDL2 may include one electrode of the capacitor Cst, for example, the second capacitor electrode CAE2. According to some embodiments, the second conductive layer CDL2 may further include at least one electrode, a wire (or a part of the at least one wire), and/or a conductive pattern (e.g., a bridge pattern). For example, the second conductive layer CDL2 may further include the back-gate electrode BG connected to the second gate electrode G2 of the second thin film transistor TFT2.

The third insulating layer 125 may be located on the second conductive layer CDL2. The third insulating layer 125 may cover the second conductive layer CDL2.

The second semiconductor layer SCL2 may be located on the third insulating layer 125. The second semiconductor layer SCL2 may include the second active layer ACT2 of the second thin film transistor TFT2. For example, the second semiconductor layer SCL2 may include the second active layer ACT2 of each of the third and fourth transistors T3 and T4.

The second active layer ACT2 may be provided on the second semiconductor layer SCL2 and may include a second semiconductor material (e.g., an oxide semiconductor) different from the first semiconductor material. For example, the second active layer ACT2 may be include any suitable active layer material including, for example, IGZO (indium (In), gallium (Ga), zinc (Zn) and oxygen (O)), IGZTO (indium (In), gallium (Ga), zinc (Zn), tin (Sn) and oxygen (O)), or IGTO (indium (In), gallium (Ga), tin (Sn), and oxygen (O)).

The second active layer ACT2 may include a second channel region CH2, a second source region S2, and a second drain region D2. The second channel region CH2 may overlap the second gate electrode G2 in the third direction DR3. The second source region S2 may be located on one side of the second channel region CH2, and the second drain region D2 may be located on the other side of the second channel region CH2. The second source region S2 and the second drain region D2 may be conductive regions by doping ions or impurities into a semiconductor for forming the second active layer ACT2. According to some embodiments, the second source region S2 may be a source electrode of the second thin film transistor TFT2. According to some embodiments, the second thin film transistor TFT2 may include a separate source electrode connected to the second source region S2. According to some embodiments, the second drain region D2 may be a drain electrode of the second thin film transistor TFT2. According to some embodiments, the second thin film transistor TFT2 may include a separate drain electrode connected to the second drain region D2.

The fourth insulating layer 126 may be located on the second semiconductor layer SCL2. The fourth insulating layer 126 may cover the second semiconductor layer SCL2.

According to some embodiments, the first insulating layer 123, the second insulating layer 124, the third insulating layer 125, and the fourth insulating layer 126 may be an inorganic insulating layer including an inorganic insulating material (e.g., silicon nitride, silicon oxide, silicon oxynitride, titanium oxide, aluminum oxide, or another inorganic insulating material), and may each have a single layer or multilayer structure. At least two insulating layers among the first insulating layer 123, the second insulating layer 124, the third insulating layer 125, and the fourth insulating layer 126 may include the same material or may include different materials. Materials of each of the first insulating layer 123, the second insulating layer 124, the third insulating layer 125, and the fourth insulating layer 126 may be variously changed according to embodiments.

The third conductive layer CDL3 may be located on the fourth insulating layer 126. The third conductive layer CDL3 may include the second gate electrode G2 of the second thin film transistor TFT2. The second gate electrode G2 may overlap a part of the second active layer ACT2 (e.g., the second channel region CH2). According to some embodiments, the third conductive layer CDL3 may further include at least one wire (or a part of the at least one wire), a conductive pattern (e.g., a bridge pattern), and/or a capacitor electrode.

According to some embodiments, each of the electrodes, the conductive patterns, and/or the wires provided in the lower conductive layer BCDL, the first conductive layer CDL1, the second conductive layer CDL2, and the third conductive layer CLD3 may include a conductive material (e.g., molybdenum (Mo), aluminum (Al), chromium (Cr), gold (Au), titanium (Ti), nickel (Ni), neodymium (Nd), copper (Cu), and at least one of other metals, alloys thereof, or other conductive materials), and may each have a single layer or multilayer structure. For example, each of the electrodes, the conductive patterns, and/or the wires provided in the lower conductive layer BCDL, the first conductive layer CDL1, the second conductive layer CDL2, and the third conductive layer CLD3 may include molybdenum (Mo) or other metal materials. At least two conductive layers among the lower conductive layer BCDL, the first conductive layer CDL1, the second conductive layer CDL2, and the third conductive layer CLD3 may include the same material or may include different materials. Materials of each of the lower conductive layer BCDL, the first conductive layer CDL1, the second conductive layer CDL2, and the third conductive layer CLD3 are not limited, and may be variously changed according to embodiments.

The valley portion VA may be formed to penetrate at least some of the plurality of insulating layers located on the substrate 110. For example, the valley portion VA may penetrate at least some of the barrier layer 121, the buffer layer 122, the first insulating layer 123, the second insulating layer 124, the third insulating layer 125, and the fourth insulating layer 126. The valley portion VA may penetrate at least some of the plurality of insulating layers overlapping the first thin film transistor TFT1 and the second thin film transistor TFT2. The valley portion VA may have a maximum depth when formed to penetrate all of the barrier layer 121, the buffer layer 122 and the first to fourth insulating layers 123, 124, 125, and 126. FIG. 9 illustrates aspects of embodiments in which the valley portion VA is formed to penetrate all of the buffer layer 122 and the first to fourth insulating layers 123, 124, 125, and 126, and is formed to penetrate a part of the barrier layer 121. Accordingly, the bottom surface of the valley portion VA may be a part of the top surface of the barrier layer 121 that is recessed by the valley portion VA. The top surface of the barrier layer 121 may be exposed by the formation of the valley portion VA, and the exposed portion may have a reduced thickness. For example, in the barrier layer 121, a thickness H1 of a portion that becomes the bottom surface of the valley portion VA may be smaller than a thickness H2 of a portion that does not overlap the valley portion VA.

However, embodiments according to the present disclosure are not limited thereto. The valley portion VA may be formed to completely penetrate the barrier layer 121 to expose a part of the top surface of the substrate 110. In this case, the bottom surface of the valley portion VA may become the top surface of the substrate 110.

The valley portion VA may be formed not to penetrate the semiconductor layers SCL1 and SCL2 and the conductive layers CDL1, CDL2 and CDL3 located between the barrier layer 121 and the fourth insulating layer 126. Among the valley portions VA, the valley portion VA formed on a portion overlapping the semiconductor layers SCL1 and SCL2 and the conductive layers CDL1, CDL2, and CDL3 may have a small depth. In FIG. 9, a portion penetrating a part of the barrier layer 121, the buffer layer 122, the first insulating layer 123, the second insulating layer 124, the third insulating layer 125, and the fourth insulating layer 126 is illustrated as a portion of the valley portion VA that does not overlap the semiconductor layers SCL1 and SCL2 and the conductive layers CDL1, CDL2, and CDL3. However, the valley portion VA may overlap at least one of the semiconductor layers SCL1 or SCL2 or the conductive layers CDL1, CDL2, or CDL3 depending on the position, and in this case, the depth may be smaller.

The valley portion VA may protect circuit elements from external impact applied to the display device 10. The valley portion VA may be formed by a process of etching lower insulating layers before the formation of the fourth conductive layer CDL4. The process of forming the valley portion VA may be performed together with a process of etching insulating layers for connecting the existing third conductive layer CDL3 and the conductive layer located thereunder, or the semiconductor layer. The display device 10 is advantageous in a fabricating process because the valley portion VA may be formed in the display area DA without an additional mask during a process of forming a through-hole where the conductive layer is located.

The fifth insulating layer 127 may be located on the third conductive layer CDL3. The fifth insulating layer 127 may cover the third conductive layer CDL3. Further, the fifth insulating layer 127 may cover the inner sidewall of the valley portion VA.

According to some embodiments, the fifth insulating layer 127 may include a first inorganic layer IL1, and a second inorganic layer IL2 located on the first inorganic layer IL1. The first inorganic layer IL1 may be directly located on the fourth insulating layer 126, the third conductive layer CDL3, and the inner sidewall of the valley portion VA. The first inorganic layer IL1 may be in direct contact with the barrier layer 121, the buffer layer 122, and the first to third insulating layers 123, 124, and 125 on the inner sidewall of the valley portion VA. The first inorganic layer IL1 may be in direct contact with a part of the top surface of the barrier layer 121 that forms the bottom surface of the valley portion VA.

The first inorganic layer IL1 and the second inorganic layer IL2 may include an insulating material, and may include different materials. According to some embodiments, the first inorganic layer IL1 may include silicon oxide (SiOₓ), and the second inorganic layer IL2 may include silicon nitride (SiNₓ). The fifth insulating layer 127 may cover the inner sidewall of the valley portion VA to prevent or reduce instances of gases generated during the formation of the sixth insulating layer 128, which will be described later, deteriorating an adjacent circuit element. In particular, the second thin film transistor TFT2 may include the second active layer ACT2 including an oxide semiconductor and the sixth insulating layer 128 may include an organic insulating material, and the fifth insulating layer 127 may prevent or reduce a gas generated in the sixth insulating layer 128 moving to the second active layer ACT2. The fifth insulating layer 127 may include a plurality of layers, and the second inorganic layer IL2 located at the upper part may include silicon nitride (SiNₓ) to effectively prevent or reduce a gas generated during the fabricating process moving to the second active layer ACT2.

The fifth insulating layer 127 covers the inner sidewall of the valley portion VA, so that the first inorganic layer IL1 and the second inorganic layer IL2 may be located at the same height as that of at least the second semiconductor layer SCL2 in the valley portion VA. For example, the first inorganic layer IL1 and the second inorganic layer IL2 may overlap the second semiconductor layer SCL2 in a direction parallel to the top surface of the substrate 110. The first inorganic layer IL1 and the second inorganic layer IL2 may be located between the second semiconductor layer SCL2 and the organic insulating material located in the valley portion VA to prevent or reduce a gas moving from the organic insulating material to the second semiconductor layer SCL2 and prevent or reduce deterioration of the second semiconductor layer SCL2.

According to some embodiments, the shortest separation distance DC between the second active layer ACT2 including an oxide semiconductor and the fifth insulating layer 127 located in the valley portion VA may be 3 micrometers (μm) or less. When the valley portion VA is formed in an area within 10 μm from the second semiconductor layer SCL2, the gas generated from the organic material filling the valley portion VA may cause deterioration of the second semiconductor layer SCL2. In order to prevent or reduce this phenomenon, the inner sidewall of the valley portion VA generated in the area within 3 μm from the second semiconductor layer SCL2 may be covered by the fifth insulating layer 127, and the shortest separation distance between the second active layer ACT2 and the fifth insulating layer 127 may be 3 μm or less.

The fourth conductive layer CDL4 may be located on the fifth insulating layer 127. The fourth conductive layer CDL4 may include the first connection electrode CNE1 (or a drain electrode of the first thin film transistor TFT1), a first bridge electrode BE1 (or a source electrode of the second thin film transistor TFT2), and a second bridge electrode BE2 (or a drain electrode of the second thin film transistor TFT2). The first connection electrode CNE1 may be provided on the fourth conductive layer CDL4 and may be connected to the first drain region D1 of the first active layer ACT1 through a first contact hole CT1 penetrating the first insulating layer 123, the second insulating layer 124, the third insulating layer 125, the fourth insulating layer 126, and the fifth insulating layer 127. The first bridge electrode BE1 may be provided on the fourth conductive layer CDL4 and may be connected to the second source region S2 of the second active layer ACT2 through a second contact hole CT2 penetrating the fourth insulating layer 126 and the fifth insulating layer 127. The second bridge electrode BE2 may be connected to the second drain region D2 of the second active layer ACT2 through a third contact hole CT3 penetrating the fourth insulating layer 126 and the fifth insulating layer 127. According to some embodiments, the fourth conductive layer CDL4 may further include at least one wire (or a part of the at least one wire), and/or a conductive pattern (e.g., a bridge pattern). For example, the fourth conductive layer CDL4 may include a part of the power line PL (e.g., the first pixel power line VDL and/or the second pixel power line VSL) provided inside and/or outside the display area DA.

The sixth insulating layer 128 may be located on the fourth conductive layer CDL4. The sixth insulating layer 128 may cover the fourth conductive layer CDL4. Further, the sixth insulating layer 128 may fill the inside of the valley portion VA and may be directly located on the second inorganic layer IL2 of the fifth insulating layer 127.

The fifth conductive layer CDL5 may be located on the sixth insulating layer 128. The fifth conductive layer CDL5 may include the second connection electrode CNE2. The second connection electrode CNE2 may be provided in the fifth conductive layer CDL5 and may be connected to the first connection electrode CNE1 through a fourth contact hole CT4 (or a first via hole) penetrating the sixth insulating layer 128. According to some embodiments, the fifth conductive layer CDL5 may further include at least one wire (or a part of the at least one wire), and/or a conductive pattern (e.g., a bridge pattern). For example, the fifth conductive layer CDL5 may include a part of the power line PL (e.g., the first pixel power line VDL and/or the second pixel power line VSL) provided inside and/or outside the display area DA.

According to some embodiments, each of the electrodes, the conductive patterns, and/or the wires provided in the fourth conductive layer CDL4 and the fifth conductive layer CDL5 may include a conductive material (e.g., molybdenum (Mo), aluminum (AI), chromium (Cr), gold (Au), titanium (Ti), nickel (Ni), neodymium (Nd), copper (Cu), and at least one of other metals, alloys thereof, or other conductive materials), and may have a single layer or multilayer structure. For example, each of the electrodes, the conductive patterns, and/or the wires provided in the fourth conductive layer CDL4 and the fifth conductive layer CDL5 may be formed of a triple layer structure of titanium/aluminum/titanium (Ti/Al/Ti). The fourth conductive layer CDL4 and the fifth conductive layer CDL5 may include the same material or may include different materials. Materials of each of the fourth conductive layer CDL4 and the fifth conductive layer CDL5 may be variously changed according to embodiments.

The seventh insulating layer 129 may be located on the fifth conductive layer CDL5. The seventh insulating layer 129 may cover the fifth conductive layer CDL5.

According to some embodiments, the sixth insulating layer 128 and the seventh insulating layer 129 may be an organic insulating layer including an organic insulating material (e.g., acrylic resin, epoxy resin, phenolic resin, polyamide resin, polyimide resin, or other organic insulating material) to planarize the circuit layer 120, and may each have a single layer or multilayer structure. The sixth insulating layer 128 and the seventh insulating layer 129 may include the same material or may include different materials. Materials of each of the sixth insulating layer 128 and the seventh insulating layer 129 may be variously changed according to embodiments.

The light emitting element layer 130 may include a pixel defining layer 131 that partitions emission areas EA of the pixels PX and the respective light emitting elements EL positioned in the respective emission areas EA. According to some embodiments, the light emitting element layer 130 may further include a spacer 132 located on a part of the pixel defining layer 131.

Each of the light emitting elements EL may include a first electrode ET1 (e.g., an anode electrode) connected to at least one transistor T (e.g., the first thin film transistor TFT1) included in the corresponding sub-pixel SPX through the first connection electrode CNE1 and/or the second connection electrode CNE2, and the light emitting layer EML and a second electrode ET2 (e.g., a cathode electrode) sequentially located on the first electrode ET1. According to some embodiments, the light emitting element EL may further include a first intermediate layer (e.g., hole layer including a hole transport layer) interposed between the first electrode ET1 and the light emitting layer EML, and a second intermediate layer (e.g., an electron layer including an electron transport layer) interposed between the light emitting layer EML and the second electrode ET2.

The first electrode ET1 of the light emitting element EL may include a conductive material and may be located on the circuit layer 120. For example, the first electrode ET1 may be located on the seventh insulating layer 129 to correspond to each emission area EA. The first electrode ET1 may be connected to the second connection electrode CNE2 through a fifth contact hole CT5 (or a second via hole) penetrating the seventh insulating layer 129.

According to some embodiments, the first electrode ET1 may include a metallic material having high reflectivity. For example, the first electrode ET1 may have a single-layer structure of molybdenum (Mo), titanium (Ti), copper (Cu) or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (AI), platinum (Pt), lead (Pb), gold (Au), or nickel (Ni).

The light emitting layer EML of the light emitting element EL may include a high molecular material or a low molecular material. According to some embodiments, the light emitting layer EML may be arranged for each sub-pixel SPX, and the light emitting layer EML of each sub-pixel SPX may emit visible light of a color corresponding to the corresponding sub-pixel SPX. According to some embodiments, the light emitting layer EML may be a common layer shared by the sub-pixels SPX of different colors, and a wavelength conversion layer and/or color filters corresponding to the color (or wavelength band) of light desired to be emitted from each sub-pixel SPX may be arranged in the emission areas EA of at least some of the sub-pixels SPX.

The second electrode ET2 of the light emitting element EL includes a conductive material and may be connected to the second pixel power line VSL. According to some embodiments, the second electrode ET2 may be a common layer formed across the entire display area DA to cover the light emitting layer EML and the pixel defining layer 131. According to some embodiments, the second electrode ET2 may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the second electrode ET2 is made of a semi-transmissive conductive material, an improvement in light output efficiency due to a micro cavity effect may be expected.

The pixel defining layer 131 may have an opening corresponding to each of the emission areas EA and may surround the emission areas EA. For example, the pixel defining layer 131 may be formed to cover an edge of the first electrode ET1 of the light emitting element EL and may include an opening exposing the remaining portion of the first electrode ET1. A region where the exposed first electrode ET1 and the light emitting layer EML overlap (or a region including the same) may be defined as the emission area EA of each pixel PX.

According to some embodiments, the pixel defining layer 131 may include at least one organic layer containing an organic insulating material. For example, the pixel defining layer 131 may include acrylic resin, epoxy resin, phenolic resin, polyamide resin, polyimide resin, unsaturated polyester resin, polyphenylene ether resin, polyphenylenesulfide resin, benzocyclobutene (BCB), or other organic insulating materials.

The spacer 132 may be located on a part of the pixel defining layer 131. The spacer 132 may include at least one organic layer containing an organic insulating material. The spacer 132 may include the same material as the pixel defining layer 131 or may include a different material from the pixel defining layer 131. According to some embodiments, the pixel defining layer 131 and the spacer 132 may be sequentially formed through separate mask processes. According to some embodiments, the pixel defining layer 131 and the spacer 132 may be simultaneously formed using a halftone mask. In this case, the pixel defining layer 131 and the spacer 132 may be integrated with each other and regarded as a single insulating layer. The organic insulating material constituting the spacer 132 is not particularly limited and may be variously changed according to embodiments.

The encapsulation layer 140 may be located on the light emitting element layer 130 in the main region MA. For example, the encapsulation layer 140 may be located in the display area DA and the non-display area NA to cover the light emitting element layer 130. The encapsulation layer 140 may block the permeation of oxygen or moisture into the light emitting element layer 130, and may reduce electrical or physical impacts to the circuit layer 120 and the light emitting element layer 130.

According to some embodiments, the encapsulation layer 140 may include a first inorganic encapsulation layer 141, an organic encapsulation layer 142, and a second inorganic encapsulation layer 143 sequentially arranged on the light emitting element layer 130. The first inorganic encapsulation layer 141 and the second inorganic encapsulation layer 143 may include an inorganic material, and the organic encapsulation layer 142 may include an organic material.

The display device 10 according to some embodiments may include the valley portion VA surrounding the area where the plurality of pixel circuits PXC are arranged, and the fifth insulating layer 127 covering the inner sidewall of the valley portion VA. The valley portion VA of the display device 10 may prevent or reduce damage to circuit elements from impact applied from the outside of the display device 10. In addition, when the display device 10 has flexible characteristics, the valley portion VA may prevent or reduce instances of cracks that may form in a plurality of insulating layers located on the substrate 110 when the substrate 110 is folded. Furthermore, the display device 10 may include the fifth insulating layer 127 located on the inner sidewall of the valley portion VA to prevent or reduce deterioration of the oxide semiconductor due to the gas generated from the organic material filling the valley portion VA.

Hereinafter, a fabricating process of the display device 10 will be described with reference to other drawings.

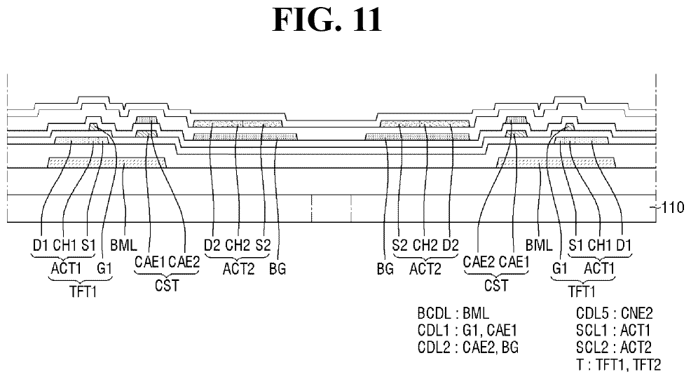

FIGS. 11 to 17 are diagrams sequentially showing a part of a fabricating process of a display device according to some embodiments.

First, referring to FIG. 11, the barrier layer 121, the lower conductive layer BCDL, the buffer layer 122, the first semiconductor layer SCL1, the first insulating layer 123, the first conductive layer CDL1, the second insulating layer 124, the second conductive layer CDL2, the third insulating layer 125, the second semiconductor layer SCL2, and the fourth insulating layer 126 are formed on the substrate 110. The lower conductive layer BCDL, the first semiconductor layer SCL1, the second semiconductor layer SCL2, the first conductive layer CDL1, and the second conductive layer CDL2 may be formed by a process of depositing materials forming them and patterning the deposited layer along a specific shape. The barrier layer 121, the buffer layer 122, and the first to fourth insulating layers 123, 124, 125, and 126 may be formed by a process of depositing a material forming the corresponding layer on the entire top surface of the substrate 110. The process of forming them may be a process that may be commonly employed in the technical field of the present disclosure.

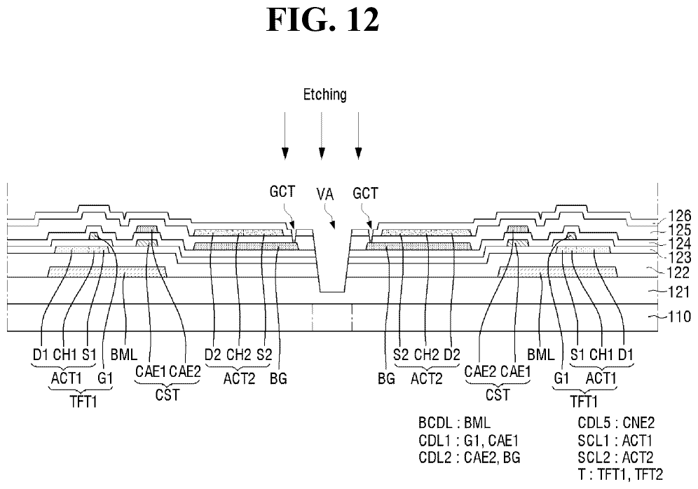

Referring to FIG. 12, in an etching process of exposing a part of the second conductive layer CDL2, a gate contact hole GCT penetrating the third insulating layer 125 and the fourth insulating layer 126, and the valley portion VA penetrating at least some of the barrier layer 121, the buffer layer 122, and the first to fourth insulating layers 123, 124, 125, and 126 are formed. This process may be performed by a process of etching a plurality of insulating layers. A process of forming the gate contact hole GCT may be an etching process for forming a path where a part of the third conductive layer CDL3 located on the fourth insulating layer 126 is electrically connected to the second conductive layer CDL2 located thereunder. In the process of forming the gate contact hole GCT, the valley portion VA may also be formed without adding a separate mask. The valley portion VA penetrates the buffer layer 122 and the first to fourth insulating layers 123, 124, 125, and 126, and penetrates only a part of the barrier layer 121, so that the bottom surface of the valley portion VA may become the top surface of the barrier layer 121. Accordingly, the thickness of the barrier layer 121 may partially vary.

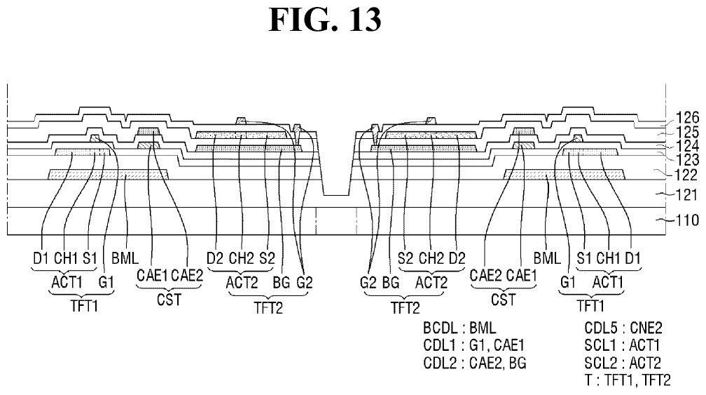

Next, referring to FIG. 13, the third conductive layer CDL3 is formed on the fourth insulating layer 126. A part of the third conductive layer CDL3, for example, the second gate electrode G2, may be in contact with the back-gate electrode BG of the second conductive layer CDL2 through the gate contact hole GCT.

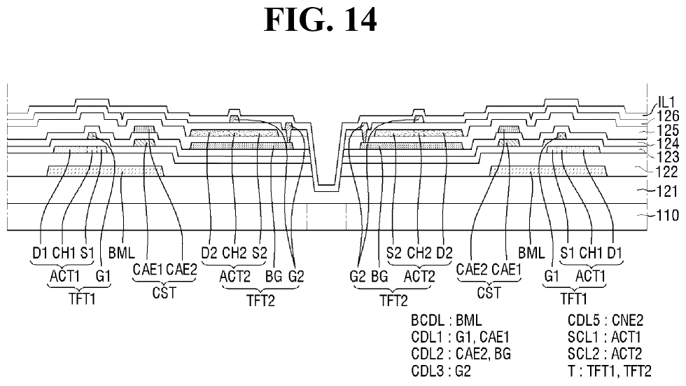

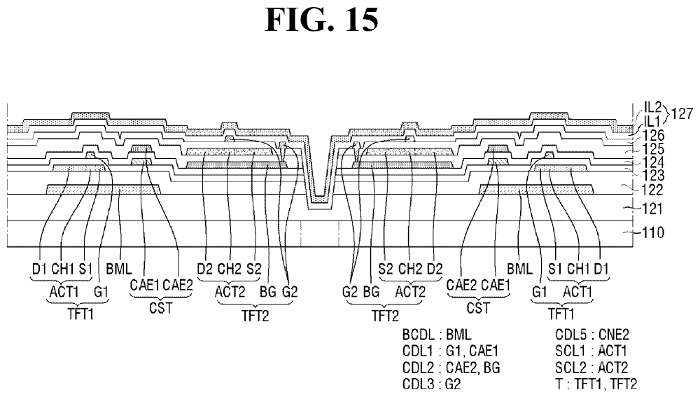

Next, referring to FIGS. 14 and 15, the first inorganic layer IL1 and the second inorganic layer IL2 are sequentially formed on the fourth insulating layer 126 and the third conductive layer CDL3 to form the fifth insulating layer 127. The first inorganic layer IL1 may be directly located on the fourth insulating layer 126 and the third conductive layer CDL3, and may be in direct contact with the inner sidewall of the valley portion VA. The first inorganic layer IL1 may be in direct contact with the barrier layer 121 on the bottom surface of the valley portion VA. The second inorganic layer IL2 may be located on the first inorganic layer IL1. The second active layer ACT2 around the valley portion VA may be shielded from the inner space of the valley portion VA by the second inorganic layer IL2.

According to some embodiments, the first inorganic layer IL1 and the second inorganic layer IL2 made of different insulating materials, for example, the first inorganic layer IL1 made of silicon oxide and the second inorganic layer IL2 made of silicon nitride, may be separately formed by individual deposition processes. The second inorganic layer IL2 including silicon nitride (SiNₓ) may be located on the first inorganic layer IL1 and effectively prevent or reduce contaminant or moisture permeation by external air.

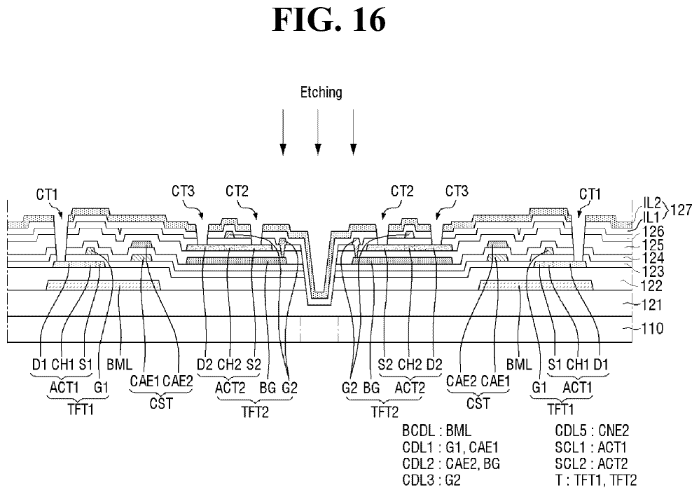

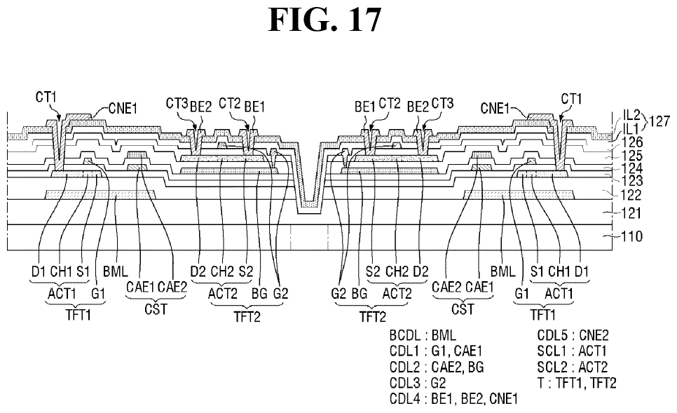

Next, referring to FIGS. 16 and 17, the contact holes CT1, CT2, and CT3 penetrating at least some of the first to fifth insulating layers 123, 124, 125, 126, and 127 are formed, and the fourth conductive layer CDL4 is formed on the fifth insulating layer 127. The fourth conductive layer CDL4 may include the plurality of bridge electrodes BE1 and BE2, and the connection electrode CNE1, and they may serve as the source electrode or the drain electrode of the first thin film transistor TFT1 and the second thin film transistor TFT2.

Next, according to some embodiments, the sixth insulating layer 128, the second connection electrode CNE2, the seventh insulating layer 129, the light emitting element layer 130, and the encapsulation layer 140 are formed on the fourth conductive layer CDL4. The sixth insulating layer 128 may include an organic insulating material, and the sixth insulating layer 128 may fill the inside of the valley portion VA. However, permeation of gases generated during the process of forming the sixth insulating layer 128 may be blocked by the inorganic layers IL1 and IL2 of the fifth insulating layer 127, and the deterioration of the second active layer ACT2 around the valley portion VA, and the second thin film transistors TFT2 may be prevented or reduced.

Hereinafter, various embodiments of the display device 10 will be described with reference to other drawings.

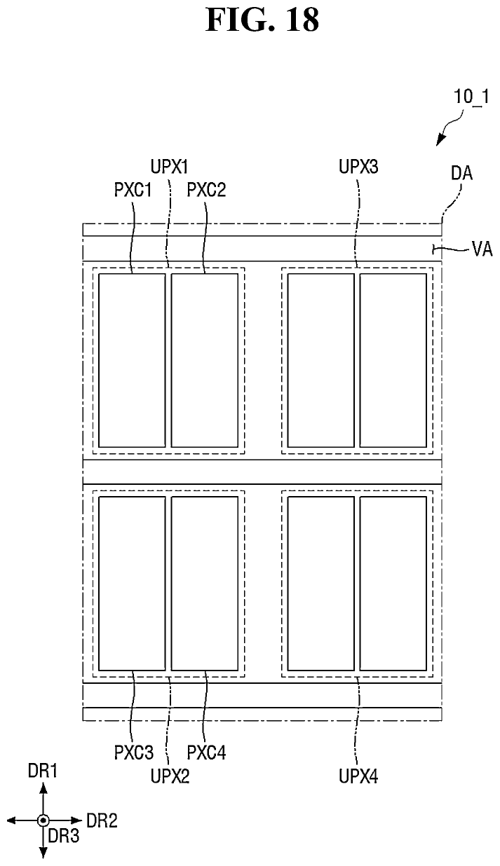

FIG. 18 is a plan view showing the arrangement of a plurality of pixels and a valley portion arranged in a display area of a display device according to some embodiments.

Referring to FIG. 18, in a display device 10_1 according to some embodiments, the valley portion VA may have a shape extending in the second direction DR2, and may be arranged in linear patterns spaced apart from each other in the first direction DR1. The valley portion VA may be located only between the unit pixel areas UPX1, UPX2, UPX3, and UPX4 adjacent in the first direction DR1, and may not be located between the unit pixel areas UPX1, UPX2, UPX3, and UPX4 adjacent in the second direction DR2. Because the valley portion VA is formed to penetrate the plurality of insulating layers, it may partially overlap wires extending in the second direction DR2 when it is formed to extend in the first direction DR1. In this case, the wires may be damaged during the process of forming the valley portion VA, so that the valley portion VA may be partially arranged as long as the impact resistance characteristics of the display device 10_1 are ensured.

For example, as shown in FIG. 18, in the display device 10_1, the valley portions VA may extend at the boundaries of the unit pixel areas UPX1, UPX2, UPX3, and UPX4 in the second direction DR2, and may not extend in the first direction DR1. Accordingly, a plurality of wires may be arranged without space restriction at the boundaries of the unit pixel areas UPX1, UPX2, UPX3, and UPX4 adjacent in the second direction DR2.

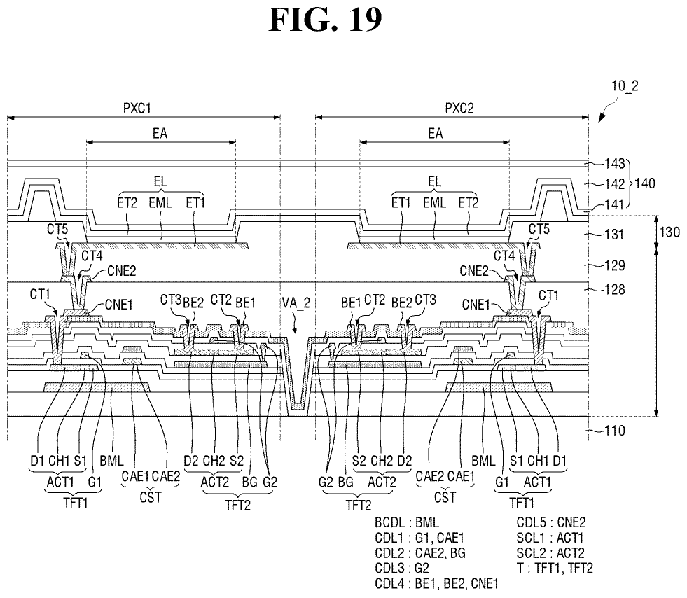

FIG. 19 is a cross-sectional view illustrating a part of a display device according to some embodiments.

Referring to FIG. 19, in a display device 10_2 according to some embodiments, a valley portion VA_2 may be formed to completely penetrate the barrier layer 121. The valley portion VA_2 may completely penetrate the barrier layer 121, and the bottom surface of the valley portion VA_2 may become the top surface of the substrate 110. Accordingly, in the fifth insulating layer 127, the first inorganic layer IL1 may be in direct contact with the top surface of the substrate 110, and may be in contact with each of the barrier layer 121, the buffer layer 122, and the first to fourth insulating layers 123, 124, 125, and 126 on the inner side surface of the valley portion VA_2. The valley portion VA_2 may also be formed in the process of forming the gate contact hole GCT, and may completely penetrate the barrier layer 121 depending on the conditions of the etching process.

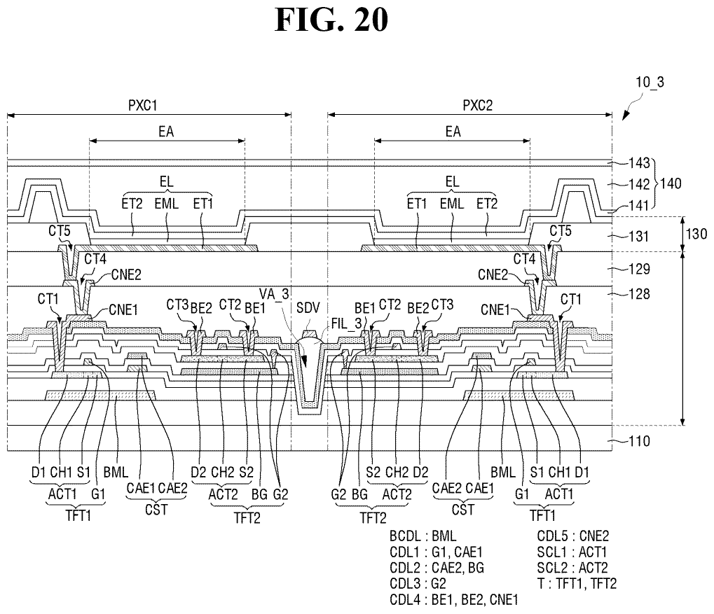

FIG. 20 is a cross-sectional view illustrating a part of a display device according to some embodiments.

Referring to FIG. 20, a display device 10_3 according to some embodiments may further include a filling layer FIL_3 that fills the inside of a valley portion VA_3 and is located on the second inorganic layer IL2 of the fifth insulating layer 127. The filling layer FIL_3 may include an organic insulating material and fill the inside of the valley portion VA_3. The filling layer FIL_3 may fill a stepped portion formed by the valley portion VA_3, and wires SDV located on the fourth conductive layer CDL4 and electrically connected to at least one of the first thin film transistor TFT1 or the second thin film transistor TFT2 may be arranged thereon.

Because the valley portion VA_3 is located in the display area DA, a large stepped portion may be formed between the periphery of the valley portion VA_3 and the inside of the valley portion VA_3. As described above, because the valley portion VA_3 extends in the first direction DR1 and/or the second direction DR2, some of the wires SDV extending in one direction in the display area DA may cross the valley portion VA_3. Some of the wires SDV may be arranged to overlap the valley portion VA_3 on the filling layer FIL_3. The filling layer FIL_3 may be arranged to fill the inside of the valley portion VA_3, and even if the wires SDV extending in one direction cross the valley portion VA_3, disconnection of the wires due to the stepped portion may be prevented or reduced.

The filling layer FIL_3 including an organic insulating material may be formed along the valley portion VA_3 to substantially flatten the stepped portion caused by the valley portion VA_3. The valley portion VA_3 may be arranged to extend at the boundaries of the unit pixel areas UPX1, UPX2, UPX3, and UPX4 in the first direction DR1 and/or the second direction DR2, and the filling layer FIL_3 may also be arranged to extend at the boundaries of the unit pixel areas UPX1, UPX2, UPX3, and UPX4 in the first direction DR1 and/or the second direction DR2 while overlapping the valley portion VA_3. The filling layer FIL_3 may fill the inside of the valley portion VA_3 to flatten the plane where the fourth conductive layer CDL4 is formed.

Further, because the inner sidewall of the valley portion VA_3 is covered by the first inorganic layer IL1 and the second inorganic layer IL2, even if the filling layer FIL_3 includes an organic insulating material, permeation of the gas formed during the fabricating process may be blocked by the second inorganic layer IL2.

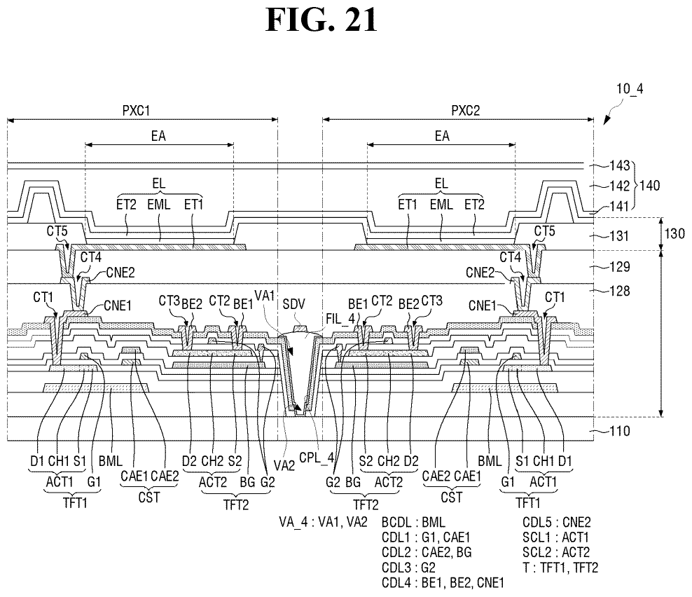

FIG. 21 is a cross-sectional view illustrating a part of a display device according to some embodiments.

Referring to FIG. 21, in a display device 10_4 according to some embodiments, a valley portion VA_4 may include a first valley portion VA1, and a second valley portion VA2 that is formed inside the first valley portion VA1 to penetrate the fifth insulating layer 127. When the first valley portion VA1 is formed to penetrate the barrier layer 121, the buffer layer 122, and the first to fourth insulating layers 123, 124, 125, and 126, the second valley portion VA2 may be formed to penetrate the fifth insulating layer 127. After the fifth insulating layer 127 that covers the inner sidewall of the first valley portion VA1 is formed, the second valley portion VA2 may be formed to penetrate them. The first valley portion VA1 and the second valley portion VA2 may be formed to overlap each other in a thickness direction, but the widths and depths thereof may be different from each other. Because the second valley portion VA2 is substantially located inside the first valley portion VA1, the width and depth of the second valley portion VA2 may be smaller than the width and depth of the first valley portion VA1.

For example, according to some embodiments in which the first valley portion VA1 is formed to penetrate the barrier layer 121, the second valley portion VA2 may penetrate the fifth insulating layer 127 to expose the top surface of the substrate 110. The bottom surface of the second valley portion VA2 may become a part of the top surface of the substrate 110. According to some embodiments in which the first valley portion VA1 penetrates only a part of the barrier layer 121, the second valley portion VA2 may penetrate the fifth insulating layer 127 and the barrier layer 121 to expose the top surface of the substrate 110. The valley portion VA_4 may have excellent impact resistance characteristics due to a double structure of the valley portions VA1 and VA2, and may considerably contribute to the flexible characteristics of the display device 10_4 when the display device 10_4 has foldable characteristics.

According to some embodiments, the display device 10_4 may further include a capping layer CPL_4 located on the second inorganic layer IL2 and located on the inner sidewall of the valley portion VA_4 and a filling layer FIL_4 that fills the inside of the valley portion VA_4. The capping layer CPL_4 may be located on the inner sidewall of the valley portion VA_4 to prevent or reduce contaminants or moisture permeation of external air, similarly to the second inorganic layer IL2 of the fifth insulating layer 127. For example, the capping layer CPL_4 may be located on the inner sidewall of the second valley portion VA2 and the bottom surface of the second valley portion VA2. The capping layer CPL_4 may be in direct contact with the first inorganic layer IL1 and the second inorganic layer IL2 of the fifth insulating layer 127 on the top surface of the substrate 110 and the inner sidewall of the second valley portion VA2. Further, the capping layer CPL_4 may be located on the second inorganic layer IL2 on the inner sidewall of the first valley portion VA1. The permeation of the gas generated during the process of forming the filling layer FIL_4 located inside the valley portion VA_4 into the second active layer ACT2 may be blocked by the second inorganic layer IL2 and the capping layer CPL_4.

In some embodiments, the capping layer CPL_4 may include silicon nitride, similarly to the second inorganic layer IL2. However, embodiments according to the present disclosure are not limited thereto. The capping layer CPL_4 may be formed of a metal wire.

The filling layer FIL_4 may be located inside the valley portion VA_4 to fill the stepped portion caused by the valley portion VA_4. Accordingly, the wires SDV may be located on the filling layer FIL_4. A description thereof is the same as described above with reference to FIG. 20.

According to some embodiments, the maximum width of the filling layer FIL_4 may be the same as the maximum width of the capping layer CPL_4. The filling layer FIL_4 and the capping layer CPL_4 may be formed by depositing materials forming them, and then patterning them along the shape of the valley portion VA_4. If the same mask is used in the patterning process of the filling layer FIL_4 and the capping layer CPL_4, two layers may be further located on the second inorganic layer IL2 even if only one mask is added. In the display device 10_4, it is possible to form each of the capping layer CPL_4 and the filling layer FIL_4 using only one mask by minimizing addition of a mask, and the maximum widths thereof, e.g., the widths measured around the upper end of the valley portion VA_4 may be the same.

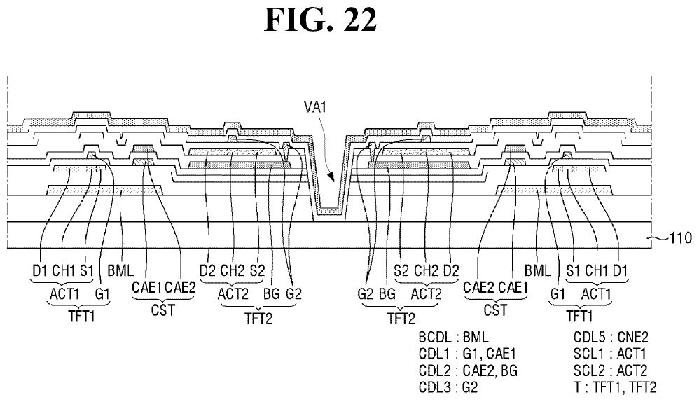

FIGS. 22 to 26 are diagrams sequentially showing a part of the fabricating process of the display device of FIG. 21.

First, referring to FIG. 22, as described above with reference to FIGS. 11 to 15, the barrier layer 121, the buffer layer 122, the lower conductive layer BCDL, the plurality of conductive layers CDL1, CDL2, and CDL3, the plurality of insulating layers 123, 124, 125, 126, and 127, the plurality of semiconductor layers SCL1 and SCL2, and the first valley portion VA1 are formed on the substrate 110. Because the description of the formation process thereof is the same as described above, the detailed description thereof will be omitted.

The first valley portion VA1 may also be formed in the process of forming the gate contact hole GCT, and may be formed to penetrate the barrier layer 121, the buffer layer 122, and the first to fourth insulating layers 123, 124, 125, and 126. The fifth insulating layer 127 may include the first inorganic layer IL1 and the second inorganic layer IL2 to cover the inner sidewall of the first valley portion VA1.

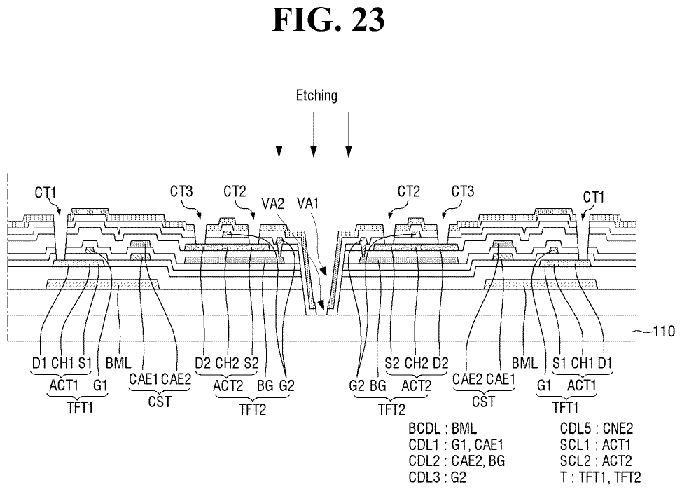

Next, referring to FIG. 23, the first to third contact holes CT1, CT2, and CT3 penetrating at least some of the first to fifth insulating layers 123, 124, 125, 126, and 127, and the second valley portion VA2 penetrating the first inorganic layer IL1 and the second inorganic layer IL2 of the fifth insulating layer 127 inside the first valley portion VA1 are formed. This process may be performed by a process of etching a plurality of insulating layers. The process of forming the first to third contact holes CT1, CT2, and CT3 may be an etching process for forming a path where a part of the fourth conductive layer CDL4 located on the fifth insulating layer 127 is electrically connected to the conductive layers CDL1, CDL2, and CDL3 located thereunder and the semiconductor layers SCL1 and SCL2. In the process of forming the first to third contact holes CT1, CT2, and CT3, the second valley portion VA2 may also be formed without adding a separate mask. The second valley portion VA2 may be formed to penetrate the fifth insulating layer 127 located inside the first valley portion VA1. Because the second valley portion VA2 is formed inside the first valley portion VA1, the width and depth thereof may be smaller than those of the first valley portion VA1. The bottom surface of the second valley portion VA2 may be the top surface of the substrate 110.

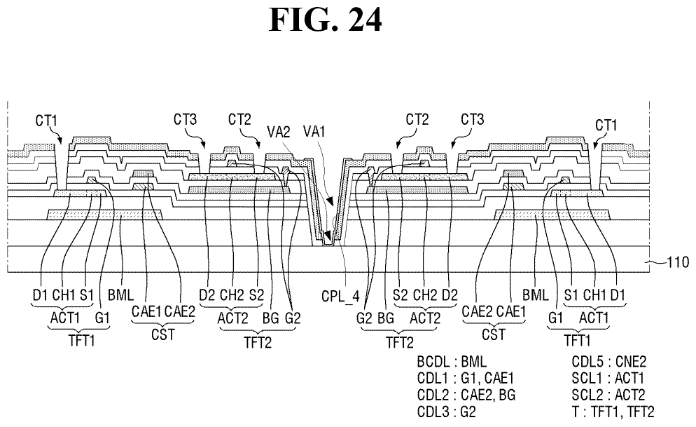

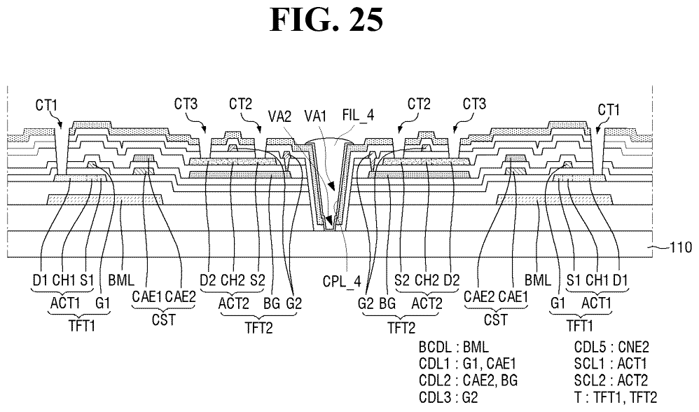

Next, referring to FIGS. 24 and 25, the capping layer CPL_4 located on the inner sidewall of the valley portion VA_4 and the filling layer FIL_4 located inside the valley portion VA_4 are formed. The capping layer CPL_4 and the filling layer FIL_4 may be entirely applied on the fifth insulating layer 127 and then patterned to correspond to the shape of the valley portion VA_4. The masks used in the process of forming the capping layer CPL_4 and the filling layer FIL_4 may be the same, and may have the same width. Alternatively, the capping layer CPL_4 and the filling layer FIL_4 may be patterned simultaneously in one mask process, and the edges thereof may be aligned side by side.

The capping layer CPL_4 may be located on the second inorganic layer IL2 inside the first valley portion VA1 while covering the inner sidewall and the bottom surface of the second valley portion VA2. The filling layer FIL_4 may fill the inside of the valley portion VA_4 to flatten the top surface of the fifth insulating layer 127.

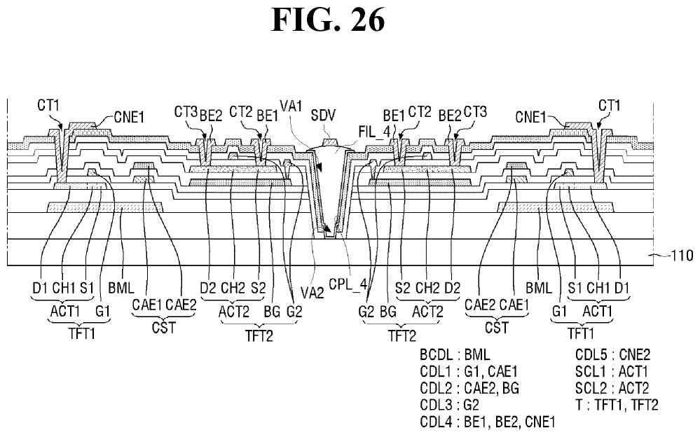

Next, referring to FIG. 26, the fourth conductive layer CDL4 is formed on the fifth insulating layer 127, and the sixth insulating layer 128, the second connection electrode CNE2, the seventh insulating layer 129, the light emitting element layer 130, and the encapsulation layer 140 are formed on the fourth conductive layer CDL4, thereby fabricating the display device 10_4.

In concluding the detailed description, those skilled in the art will appreciate that many variations and modifications can be made to the disclosed embodiments without substantially departing from the spirit and scope of embodiments according to the present disclosure. Therefore, the disclosed embodiments of the invention are used in a generic and descriptive sense only and not for purposes of limitation.

What is claimed is:

1. A display device comprising:
a barrier layer on a substrate;
a buffer layer on the barrier layer;
a first active layer of a first thin film transistor on the buffer layer;
a first insulating layer on the first active layer;
a first conductive layer on the first insulating layer and comprising a first gate electrode overlapping the first active layer;
a second insulating layer on the first conductive layer;
a second conductive layer on the first conductive layer and comprising a back gate electrode overlapping a second active layer of a second thin film transistor;
a third insulating layer on the second conductive layer;
the second active layer on the third insulating layer and overlapping the back gate electrode;
a fourth insulating layer on the second active layer;
a valley portion penetrating at least some of the barrier layer, the buffer layer, and the first to fourth insulating layers without overlapping the first active layer and the second active layer;
a third conductive layer on the fourth insulating layer and comprising a second gate electrode overlapping the second active layer;
a fifth insulating layer on the third conductive layer and the fourth insulating layer and covering an inner sidewall of the valley portion; and
a light emitting element on the fifth insulating layer and electrically connected to the first thin film transistor and the second thin film transistor, respectively,
wherein the fifth insulating layer comprises a first inorganic layer directly on the inner sidewall of the valley portion, and a second inorganic layer containing a material different from the first inorganic layer and on the first inorganic layer.

2. The display device of claim 1, wherein the first inorganic layer comprises silicon oxide, and
the second inorganic layer comprises silicon nitride.

3. The display device of claim 1, wherein the valley portion is formed such that a part of a top surface of the barrier layer or the buffer layer is recessed, and
the first inorganic layer directly contacts a part of the top surface of the barrier layer or the buffer layer.

4. The display device of claim 3, wherein in the barrier layer, a thickness of a portion forming a bottom surface of the valley portion is smaller than a thickness of a portion which does not overlap the valley portion.

5. The display device of claim 3, wherein the first inorganic layer directly contacts each of the buffer layer, the first insulating layer, the second insulating layer, and the third insulating layer on the inner sidewall of the valley portion.

6. The display device of claim 1, wherein the valley portion penetrates the barrier layer and exposes a top surface of the substrate, and
the first inorganic layer directly contacts the substrate.

7. The display device of claim 1, further comprising a filling layer filling an inside of the valley portion and is on the second inorganic layer,
wherein the filling layer contains an organic insulating material.

8. The display device of claim 7, further comprising wires electrically connected to at least one of the first thin film transistor or the second thin film transistor,
wherein at least one of the wires overlaps the valley portion on the filling layer.

9. The display device of claim 1, wherein the valley portion comprises a first valley portion and a second valley portion overlapping the first valley portion and penetrating the fifth insulating layer, and
the second valley portion is inside the first valley portion.

10. The display device of claim 9, wherein a depth of the second valley portion is smaller than a depth of the first valley portion, and
a width of the second valley portion is smaller than a width of the first valley portion.

11. The display device of claim 9, further comprising:
a capping layer on the second inorganic layer on the valley portion and on an inner sidewall of the second valley portion, and
a filling layer on the capping layer and filling an inside of the valley portion.

12. The display device of claim 11, wherein the capping layer and the filling layer have a same maximum width.

13. The display device of claim 1, wherein a separation distance between the valley portion and the second active layer is 3 micrometers (μm) or less.

14. The display device of claim 1, wherein the substrate comprises a plurality of unit pixel areas where the first thin film transistor and the second thin film transistor are located, and
the valley portion is at a boundary between the unit pixel areas adjacent to each other.

15. A method of fabricating a display device, comprising:
forming a first semiconductor layer, a first insulating layer, a first conductive layer, a second insulating layer, a second semiconductor layer, a third insulating layer, a second conductive layer, and a fourth insulating layer on a substrate, and forming a gate contact hole penetrating the third insulating layer, and a valley portion penetrating the second to fourth insulating layers;
forming a second insulating layer comprising a first inorganic layer covering an inner sidewall of the valley portion, and a second inorganic layer on the first inorganic layer; and
forming a plurality of contact holes penetrating at least some of the second to fourth insulating layers, and forming a plurality of bridge electrodes on the fourth insulating layer and connected to at least one of the first semiconductor layer or the second semiconductor layer through the contact holes,
wherein the first inorganic layer and the second inorganic layer contain different materials.

16. The method of claim 15, wherein the first inorganic layer comprises silicon oxide, and
the second inorganic layer comprises silicon nitride.

17. The method of claim 15, further comprising forming a buffer layer between the substrate and the first semiconductor layer, and a barrier layer between the buffer layer and the substrate, wherein
the valley portion is formed such that a part of a top surface of the barrier layer or the buffer layer is recessed while penetrating the barrier layer or the buffer layer, and
the first inorganic layer is in direct contact with a part of the top surface of the barrier layer or the buffer layer.

18. The method of claim 15, further comprising forming a buffer layer between the substrate and the first semiconductor layer, and a barrier layer between the buffer layer and the substrate, wherein
the valley portion is formed to penetrate the buffer layer and the barrier layer, and
the first inorganic layer is in direct contact with a part of a top surface of the substrate.

19. The method of claim 15, wherein in the forming of the plurality of contact holes, the first inorganic layer and the second inorganic layer are partially penetrated inside the valley portion, and
the valley portion comprises a first valley portion, and a second valley portion penetrating the first inorganic layer and the second inorganic layer.

20. The method of claim 19, further comprising forming a capping layer on an inner sidewall of the second valley portion and the second inorganic layer, and a filling layer filling an inside of the valley portion.
